(19) United States
(12) Patent Application Publication
(10) Pub. No.: US 2026/0160816 A1
(43) Pub. Date: Jun. 11, 2026

(54) BATTERY MANAGEMENT SYSTEM

(71) Applicant: Allison Transmission, Inc., Indianapolis, IN (US)

(72) Inventor: Hugo Martin, La Eliana (ES)

(73) Assignee: Allison Transmission, Inc., Indianapolis, IN (US)

(21) Appl. No.: 18/682,485

(22) PCT Filed: Feb. 2, 2024
(86) PCT No.: PCT/ES2024/070062

§ 371 Date: Feb. 9, 2024

(51) Int. Cl. G01R 31/382; B60L 50/60; B60L 53/62; B60L 58/12; B60L 58/18; G01R 31/367; G01R 31/396

(52) U.S. Cl. CPC G01R 31/382; B60L 50/60; B60L 53/62; B60L 58/12; B60L 58/18; G01R 31/367; G01R 31/396

(57) ABSTRACT

A system and method for determining an internal state of a battery that synchronizes the overall available charge and discharge power with the present charge and discharge current limits. The system may be operable to determine a current limit for the battery according to an internal state of the battery, a voltage based current limit, and a merged current limit. The system may also be configured to determine an expected voltage based on the current limit, and to optionally determine an overall available power output based on the current limit and the expected voltage.

### BACKGROUND

As more and more devices migrate toward using batteries instead of other sources of power, it becomes increasingly more important for these devices to manage their power consumption to maximize the performance of the batteries. This may be particularly important for hybrid or electric vehicles where the voltage, current, and power involved is large, and where failure to properly manage demands on the battery may result in reduced battery life or possibly catastrophic failure of the battery. Thus optimizing management of the state of power for a battery is becoming ever more important.

### SUMMARY

Disclosed is a battery management system and a method of operating the system. In one aspect, the disclosed system may be configured to synchronize current and power limits during charging and discharging of a battery, or in a collection of batteries operating as one.

In one general aspect, the method optionally includes determining an internal state of a battery based on a present current draw on the battery. This may be accomplished by using an equivalent circuit model implemented in a battery management circuit, such as, for example, a second order equivalent circuit model. The disclosed equivalent circuit models may be implemented in hardware, software, or any combination thereof and may optionally be operated in a forward mode or a reverse mode. In the forward mode, the equivalent circuit model accepts a current as input, and provides a voltage as output. In the reverse mode, the disclosed equivalent circuit model accepts a voltage as input, and provides a current as output.

The disclosed method may also include the action of determining calibration information that may be used by the management system to regulate or fine-tune the disclosed calculations. In one aspect, the calibration information optionally includes maximum and minimum operating temperatures for the battery, and the system may include one or more temperature sensors arranged and configured to sense the present temperature of the battery at any time. In another example, the calibration information includes a state of charge estimation for the battery, and the system may be configured to determine this estimated state of charge, or to obtain it from a device or system separate from the disclosed system.

Other examples of calibration information include, but are not limited to a maximum operating cell voltage of the battery, component current limits specific to individual components electrically connected to the battery such as busbars, contactors, inverters, converters, and the like, a peak current limit for the battery specifying the maximum instantaneous current that can be drawn from the battery at any given time, or a continuous current limit specifying the maximum current that may be continuously drawn from the battery over an extended period of time. In another aspect, the calibration information may be obtained by experimentation and/or from the battery or cell manufacturer.

The disclosed method optionally includes the action of determining a current limit specifying a maximum charge or discharge current that may be provided to or obtained from the battery. This may include determining multiple current limits and optionally selecting the lowest limit.

In one aspect, determining the current limit optionally includes determining component current limits, such as by referring to the calibration information, or by other means. In another aspect, determining the current limit may include determining a merged current limit that takes into consideration the peak current limit and the continuous current limit, along with the present current load on the battery, either while charging or discharging the battery. In another aspect, determining a current limit may include determining a voltage based current limit that optionally includes calculating what charge or discharge current, if applied, would cause the battery cell voltage to reach or exceed a voltage operating limit of the battery. In another aspect, this voltage based current limit may be obtained using a second order equivalent circuit model running in the reverse mode according to the system and method of the present disclosure.

In another aspect, the disclosed method optionally includes the action of determining a power limit for either charge or discharge power. In one aspect, determining a power limit may include determining a predicted voltage when the battery operates at the previously determine current limit. A candidate, or predicted, power limit may be determined using the current limit and the predicted voltage. The predicted voltage is optionally adjusted based on the present current and power load in order to determine an overall available power limit.

The battery management system of the present disclosure may include a battery management circuit that is configured to execute actions taken by the disclosed method to obtain the current power limits for a battery, or for multiple batteries. The battery management circuit of the present disclosure may include control logic that includes circuit models, control modules, and the like. The control logic may be implemented as hardware, software or any combination thereof suitable for the performance of the disclosed method.

Other aspects of the battery management circuit optionally include one or more Proportional and Integral (PI) or Proportional, Integral, and Derivative (PID) controllers, and/or one or more sensors such as might be operable to determine battery temperature, present current and/or power load, and the like. In another aspect, the battery management circuit may include a processor which may be arranged and configured to execute the control logic, and to optionally perform other tasks. A memory may be included for storing information about the system as it operates, including settings, operating profiles, present, past, or predicted values resulting from calculations performed by the processor and/or the control logic, and the like. A communication interface may also be included and may be operable to create and/or maintain communication links with other systems or devices such as a vehicle control circuit, electric motor controller, transmission controller, and the like.

Further forms, objects, features, aspects, benefits, advantages, and examples of the present invention will become apparent from the detailed description and drawings provided herewith.

### BRIEF DESCRIPTION OF THE DRAWINGS

FIG. 1 is a component diagram illustrating one example of the components that may be included in the battery management system of the present disclosure.

FIG. 2 is a circuit diagram illustrating one example of an equivalent circuit model that may be used by the battery management system of the present disclosure.

FIG. 3 is a flowchart illustrating one example of the actions that may be taken by the battery management system of the present disclosure.

FIG. 4 is a diagram illustrating one example of actions the battery management system of the present disclosure may perform to determine calibration information.

FIG. 5 is a flowchart illustrating one example of actions the battery management system of the present disclosure may perform to determine a charge or discharge current limit.

FIG. 6 is a flowchart illustrating one example of actions the battery management system of the present disclosure may perform to determine a merged current limit.

FIG. 7 is a flowchart illustrating one example of actions the battery management system of the present disclosure may perform to determine a voltage based current limit.

FIG. 8 is a flowchart illustrating one example of actions the battery management system of the present disclosure may perform to determine a charge or discharge power limit.

FIG. 9 is a component diagram illustrating one example of the battery management system of the present disclosure in use in an energy storage system having multiple batteries or battery cells.

FIG. 10 is a component diagram illustrating another example of the battery management system of the present disclosure in use in an energy storage system having multiple batteries or battery cells.

FIG. 11 is a component diagram illustrating an example of the battery management system of the present disclosure in use in a vehicle.

FIG. 12 is a component diagram illustrating an example of a battery management circuit that may be used in a battery management system of the present disclosure.

### DETAILED DESCRIPTION

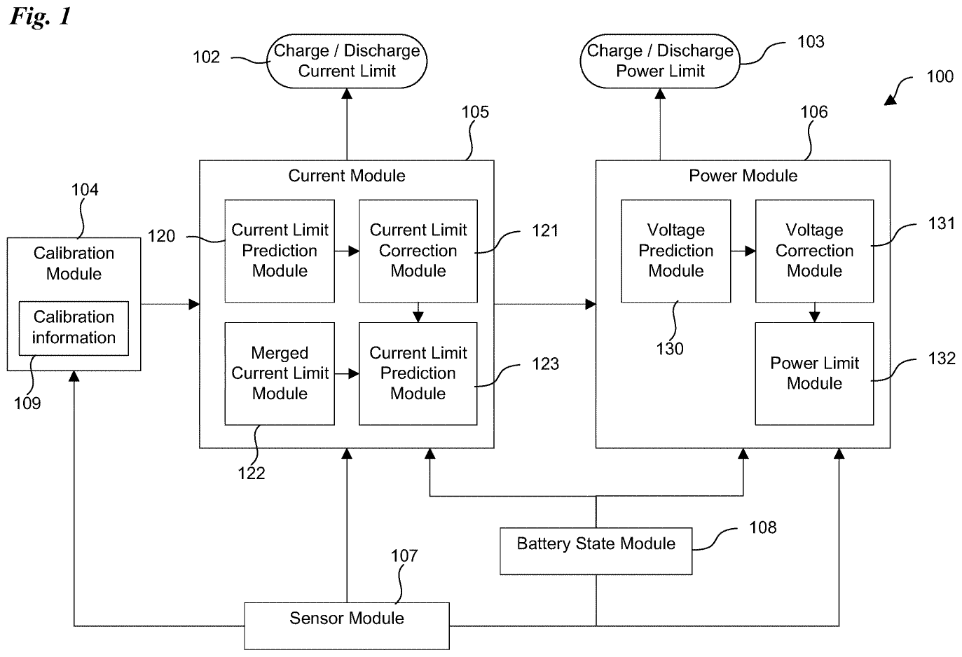

FIG. 1 is a component diagram illustrating at 100 one example of components that may be included in a battery management system of the present disclosure. The battery management system 100 optionally includes a calibration module 104, a current module 105, a power module 106, a sensor module 107, and/or a battery state module 108. Other components may be included as well. The illustrated components may be implemented in hardware or software, or any combination thereof. For example, each component may be implemented as code segments, objects, subroutines, functions, packages, or via any other suitable software construct. With respect to the software aspects, software components, or portions of components, disclosed herein may be executed by a processor, microcontroller, logic circuit, or other hardware. In another example, components of the present disclosure may be implemented in hardware using logic circuits, Field Programmable Gate Arrays (FPGAs), Application Specific Integrated Circuits (ASICs), or other circuits that include analog or digital logic, or any combination thereof.

In one aspect, the calibration module 104 may be configured to calculate, obtain, access, or otherwise determine calibration information 109. The calibration information 109 optionally includes information about the battery, or batteries, as well as any other relevant information, that may be useful to account for the various factors that may be useful to consider in comparing and manipulating data about the batteries so as to efficiently and effectively manage the present current and power loads on the battery.

For example, the manufacturer of the battery may provide the individual values for a portion of the calibration data. These values may be included in calibration information 109 and stored in a memory of the disclosed system. In another example, the calibration information 109 may be determined by experimentation and stored in memory in a data store that preferably provides rapid access to both read and update the data.

In one aspect, individual battery cells may be uniquely identifiable and may be managed separately. Calibration information 109 may be determined for each battery by experimentation and these battery specific values may be stored in the calibration module 104. The unique calibration values for each cell may be stored independently of other cells so that the individual values may be accessed for each battery of a collection of batteries. In another aspect, the calibration information 109 may include values defining characteristics of a group of batteries operating as one battery array. In this configuration, the specific characteristics of an individual battery cell are not considered in favor of operating on the entire array as a single unit having multiple cells likely connected together to form a “battery” in the aggregate. Thus calibration values may be specific to a battery cell or generalized to include data about multiple individual battery cells, or any combination thereof.

In one aspect, the calibration information 109 of calibration module 104 includes maximum and minimum operating temperatures for the battery, an estimated state of charge of the battery, a maximum operating voltage for the battery, a peak current limit specifying a maximum instantaneous current that can be drawn from the battery, and/or a continuous current limit specifying a maximum current that may be continuously drawn from the battery over a specified period of time. This specified period of time may be any suitable time, such as less than 10 seconds, less than 1 minute, less than 5 minutes, or 5 minutes or more. Generally, the peak current limit is greater than the continuous current limit. In another aspect, the peak current limit is optionally determined by The system of the present disclosure based on real-time operational factors such as the present battery temperature and/or the present battery state of charge.

In another aspect, the calibration information 109 of calibration module 104 optionally includes a state of charge estimation for the battery, and the calibration module 104 is optionally configured to determine an estimated state of charge, or to receive an estimated state of charge from an external system or source. In another aspect, the calibration information 109 retained by calibration module 104 optionally includes a maximum operating cell voltage.

In another aspect, the calibration information 109 maintained by a calibration module 104 includes component current limits for individual components electrically connected to the battery such as bus bars, contactors, electronic circuits, inverters, converters, and the like. These components may, for example, be part of a vehicle drive system such as for an electric or hybrid vehicle that uses one or more electric motors electrically connected to the battery. In this example, the disclosed battery management system may be useful for managing the power and current limits for an electric or hybrid vehicle.

The sensor module 107 may be operable to obtain input from one or more sensors indicating aspects of the battery that may be useful for the determination of current and power limits or other aspects of battery management according to the present disclosure. In another aspect, the present current draw on the battery is optionally determined individually for one battery cell, or for multiple battery cells electrically connected together and operating as a single battery module. Sensors may be configured to detect the disclosed aspects such as temperature, current, voltage, and the like, individually for a single battery cell, or in aggregate for multiple battery cells taken together.

The present current draw on the battery may, for example, be determined using a current sensing circuit that may include but is not limited to, components such as shunt resistors, Hall Effect sensors, and the like. In one aspect, the sensor module 107 is optionally responsive to sensors or sensor output obtained from other sensor systems, controllers, control circuits, and the like. In another aspect, the sensor module 107 optionally includes a temperature sensor arranged and configured to sense the present temperature of the battery. In another aspect, the sensor module 107 may obtain sensor input from the battery cells themselves in the instance where the batteries are operable to provide such output.

The battery state module 108 may be arranged and configured to calculate, predict, model, or otherwise determine information about the internal state of the battery (or batteries). The battery state module 108 optionally includes one or more equivalent circuit models along with other control logic useful in determining specific operating characteristics or behavior of the battery.

In one aspect, a battery cell under load generally has a voltage that is different from its nominal equilibrium voltage. For example, the voltage may be lower for discharge, and higher for charge due to different factors which include, but are not limited to, the batteries ohmic resistance, its charge transfer resistance, and its diffusion resistance. Ohmic resistance generally refers to the electronic and ionic resistances of the cell components such as the electrolyte conductivity, separator and electrical connections (terminals, current collectors, weld joints and contacts in electrodes). Charge transfer resistance generally refers to a resistance generated by the electrochemical reactions in the electrodes. In the case of a lithium-ion battery, diffusion resistance generally refers to the localized increase or reduction of Li+ concentration in the electrodes and the electrolyte. In one aspect, the battery state module 108 optionally includes one or more equivalent circuit models that may be used by the system to calculate specific reactions in the battery cells depending on predicted changes in voltage and current in one example, battery state module 108 includes a second order equivalent circuit model. A second order equivalent circuit model may be preferred because it is generally a computationally efficient battery model that characterizes the input/output behavior of the cell regardless of its physics.

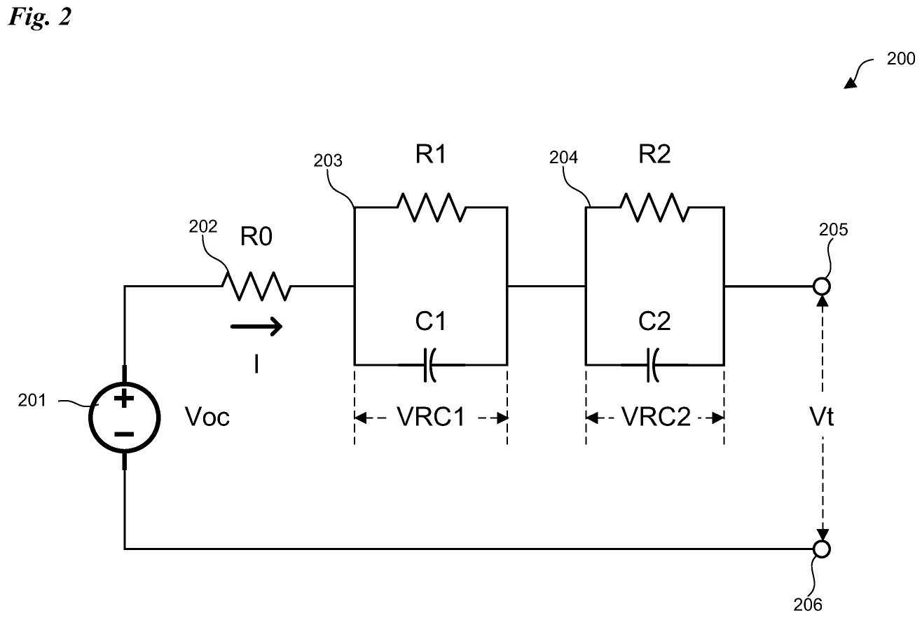

FIG. 2 is a circuit diagram illustrating one example of an equivalent circuit model that may be used throughout The system of the present disclosure. A second order equivalent circuit model 200 is illustrated that may be used by the battery state module 108 to determine aspects of the internal state of the battery. A battery 201 defines an ideal open circuit voltage VOC which generally refers to the voltage differential detectable at the positive and negative terminals of an ideal battery. A circuit 202 optionally models the ohmic resistance, a circuit 203 optionally models the charge transfer resistance, and a circuit 204 optionally models the diffusion resistance. In this example of an equivalent circuit model for a battery, circuits 202, 203, and 204 are electrically connected in series between the ideal battery 201 and an output terminal 205.

Circuit 202 includes a resistor R0 through which the present battery current I is flowing. Circuit 203 includes a charge transfer resistance shown as resistor R1, and a charge transfer capacitance shown as capacitor C1. R1 and C1 are electrically connected in parallel such that a voltage VRC1 represents a charge transfer voltage drop across R1 and C1. In another aspect, circuit 204 includes a diffusion resistance as a resistor R2, and a diffusion capacitance as a capacitor C2. R2 and C2 are electrically connected in parallel such that a voltage VRC2 represents a diffusion voltage drop across R2 and C2. A terminal voltage Vt is included in the model which represents the actual measured potential difference across the battery that is presented to circuits electrically connected to the positive and negative battery terminals 205 and 206 respectively.

Using a second order equivalent circuit model of the battery state module 108, the disclosed system is optionally configured to determine aspects of the state of the battery according to this model. For example, battery state module 108 is optionally configured to determine the internal cell state of the battery VRC1 and VRC2. These internal states of the battery VRC1 and VRC2 are optionally calculated using the present current draw on the battery (illustrated in FIG. 2 as I). The present current draw on the battery may, for example, be obtained from the sensor module 107.

One example of an equation that may be implemented by the battery state module to determine the state of VRC1 is:

$$\frac{dVRC 1}{dt} = - \frac{VRC 1}{R 1 C 1} - \frac{1}{C 1}$$

The battery state module 108 may optionally implement the following equation to determine the state of VRC2 according to as follows:

$$\frac{dVRC 2}{dt} = - \frac{VRC 2}{R 2 C 2} - \frac{1}{C 2}$$

The battery state module 108 may implement the following equation to determine the battery voltage Vt:

$$Vt = VRC 1 + VRC 2 + Voc - I * R 0$$

In another aspect, the parameters Voc, R0, R1, C1, R2, C2 are optionally extracted from cell testing in the lab by sampling for these aspects of the battery when the battery is at varying states of charge and at varying temperatures using a Hybrid Pulse Power Characterization (HPPC) cycle. The results may then be stored in the battery state module 108 to allow the battery state to be quickly determined in real time.

In another aspect, battery state module 108 may be configured with multiple circuit models like the one shown in FIG. 2. Individual models may be configured differently in the battery state module 108 to determine different aspects of the state of the battery, or to determine the state of the battery in different ways.

In one example, a second order equivalent circuit model of the present disclosure may include a “forward” and optionally a “reverse” mode. In the forward mode, the model may be used to calculate an output voltage based on an input current. In the reverse mode, an input voltage is optionally used to determine an output current. For example, the battery state module 108 may be programmed or otherwise configured to implement a second order equivalent circuit model operating in the reverse mode to determine a battery current draw that would cause the battery voltage to meet or exceed a voltage operating limit for the battery. In another aspect, the battery state module 108 may include a second order equivalent circuit model configured to operate in the forward mode to determine VRC1 and VRC2 based on the present current draw (I).

Turning now to the remaining modules illustrated in FIG. 1, the current module 105 may be arranged and configured to calculate, predict, or otherwise determine a charge or discharge current limit 102 for the battery (or batteries in the aggregate). The current module 105 optionally includes a current limit prediction module 120, a current limit correction module 121, a merged current limit module 122, and a current limit prediction module 123.

The current limit prediction module 120 includes hardware and/or software that is optionally arranged and configured to determine a predicted voltage based current limit based on a maximum voltage limit for the battery. In one example, the predicted voltage based current limit is optionally calculated using a second order equivalent circuit model of the present disclosure configured to operate in the reverse mode where an input voltage is used to determine a predicted output current. In this instance, the input voltage is optionally the maximum voltage limit for the battery. Put another way, the predicted voltage based current limit may be determined by calculating what would be the current that makes the battery voltage meet the voltage operating limit for the battery, and optionally without exceeding it. In another aspect, the predicted voltage based current limit may be calculated according to the maximum operating voltage for the battery and/or the internal battery cell states VRC 1 and VRC 2.

In another aspect, the current limit correction module 121 is an aspect of the system that is arranged configured using hardware, software, or any combination thereof, to determine a correction factor to be applied to the predicted voltage based current limit in order to obtain the final voltage based current limit. The correction factor may be helpful in accounting for error that may creep into the calculations being made by the circuit models of the present disclosure. Such errors may occur, for example, as the state of health of the battery degrades over time.

In one example, the correction factor for the predicted voltage based current limit is optionally calculated according to the maximum operating voltage for the battery, and/or the present battery voltage. The voltage based current limit may be determined by applying the correction factor to the predicted voltage based current limit to determine the final voltage based current limit. In one example, the voltage based current limit is optionally determined by multiplying the predicted voltage based current limit by the correction factor. The correction factor, may, in that instance, be a number greater than zero and less than 2.0.

In another aspect, the correction factor for the voltage based current limit may be determined by the current limit correction module 121 using a controller such as a PI or PID controller that is arranged and configured to operate as a closed-loop control to address errors in the predicted voltage based current limit. The controller may be an individual hardware element included as part of the circuitry of the current limit correction module 121, or in another example, the controller may be implemented in software executed by a processor that is shared by other modules of the battery management circuit.

The merged current limit module 122 provides an additional calculation of a current limit that is based on the current draw from the battery considered in concert with the peak current draw and the continuous current draw of the battery. The merged current limit module 122 is thus arranged and configured to determine a current limit by merging these aspects. Generally the resulting merged current limit may be used as an upper limit so that the present current drawn from the battery is generally less than or equal to the merged current limit.

In another aspect, the merged current limit module 122 is optionally configured to automatically adjust the merged current limit over time. For example, the merged current limit module 122 may determine a merged current limit that is equal to the peak current limit for a predetermined grace period during which the resulting merged current limit may be higher than the continuous current limit for the battery. In another aspect, the merged current limit module 122 may be configured to automatically decrease the merged current limit over time after the grace period expires. In another aspect, the merged current limit module 122 may be configured to adjust the merged current limit in the direction of the peak current limit after the rest period has expired. In another aspect, the merged current limit module 122 may be configured to automatically decrease the merged current limit when the merged current limit is greater than the continuous current limit. The merged current limit module 122 may be configured to optionally increase the merged current limit to be greater than or equal to the continuous current limit when the present current drawn by the battery is less than the continuous current limit. In another aspect, the merged current limit module 122 may be configured to maintain the merged current limit at the continuous current limit for a predetermined rest period of time while the present current drawn by the battery is less than or equal to the continuous current limit and the merged current limit.

The merged current limit module 122 may be configured or programmed to adjust the merged current limit to increase it as needed using a linear, geometric, exponential, or other suitable rate of change. The rate of change of the merged current limit is optionally automatically adjusted by the merged current limit module 122.

The current limit module 123 is optionally arranged and configured to make a final determination on the current limit based on the current limits determined by the current limit prediction module 120, the current limit correction module 121, and the merged current limit module 122. In one aspect, the current limit module 123 may be arranged and configured to compare the current limits from modules 120, 121, and 122, with component current limits obtained from calibration information 109. In this example, the current limit for the charge or discharge of the battery is optionally determined according to the voltage based current limit, the components current limit, and the merged current limit. In one instance the current limit module 123 may include hardware or software arranged and configured to determine the discharge or charge current limit 102 by selecting the minimum of the voltage based current limit, the components current limit, and the merged current limit.

The power module 106 is optionally arranged and configured to calculate or otherwise determine a charge or discharge power limit 103 for the battery (or for multiple batteries operating in concert). The power module 106 is optionally configured to determine a power limit 103 for charge and/or discharge that is in sync with the current limit 102. The power module 106 optionally includes a voltage prediction module 130, a voltage correction module 131, and a power limit module 132.

In one aspect, the voltage prediction module 130 includes circuitry and/or software that is optionally configured to use a second order equivalent circuit model of the present disclosure operating in a forward mode to determine a predicted battery voltage when the battery provides the charge or discharge current limit. In another aspect, the voltage prediction module 130 may be configured to determine the predicted battery voltage according to the charge or discharge current limit 102 while also considering the present current draw on the battery. The result is optionally the expected voltage of the battery when delivering the charge or discharge current limit 102.

The voltage correction module 131 may include hardware and/or software that is optionally configured to determine a correction offset to apply to the battery voltage determined by the voltage prediction module 130. This correction offset from the voltage correction module may be used to synchronize the power and current limits. In one aspect, the voltage correction module 131 may be arranged and configured to determine the offset according to the charge or discharge current limit while to, the present current draw on the battery, and the present power output of the battery. In another aspect, correction offset to apply to the predicted battery voltage may be calculated using a controller such as a PI or PID controller. This controller may be implemented in hardware, software, or any combination thereof.

The power limit module 132 includes hardware and/or software that may be configured to determine an overall charge or discharge power limit 103 that is optionally synchronized with the charge or discharge current limit 102. In one aspect, the power limit is optionally calculated according to the charge or discharge current limit 102, the predicted battery voltage obtained from the voltage prediction module 130 and optionally corrected according to an offset determined by the voltage correction module 131. The power limit module 132 may be arranged and configured to determine the overall power limit 103 such as by multiplying the charge or discharge current limit 102 with the corrected predicted battery voltage. In another aspect, the charge or discharge power limit 103 may be calculated by determining the power limits for one or more battery cells and combining them together. In another aspect, the charge or discharge power limit 103 may be calculated for a collection of battery cells electrically connected together and thus appearing to the battery management system of the present disclosure as a single battery.

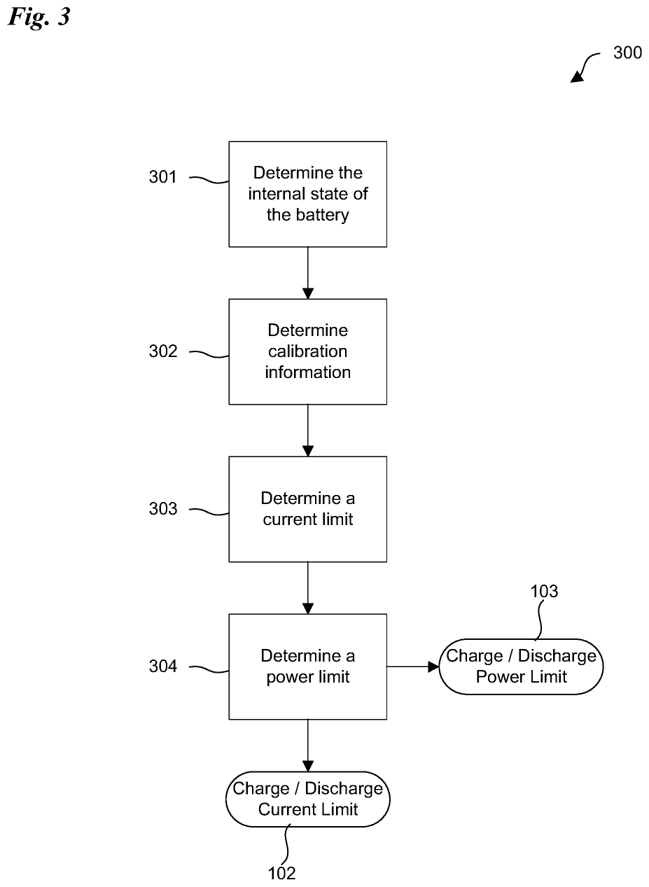

Illustrated at 300 in FIG. 3 is one example of the actions that may be taken by the battery management system of the present disclosure in estimating voltage, current, and/or power limits for a battery, or a collection of batteries operating in aggregate. At 301, the system may determine the internal state of the battery. Any suitable aspect or module of the disclosed system may be employed as needed such as, for example the battery state module 108 and/or the sensor module 107, and others.

In another aspect, determining aspects of the state of the battery at 301 may include using a second order equivalent circuit model like the one illustrated in FIG. 2 and discussed above. Aspects of the internal state of the battery that may be determined include, but are not limited to the open circuit voltage VOC, the ohmic resistance of the battery R0, the charge transfer resistance R1, the charge transfer capacitance C1, the diffusion resistance R2, the diffusion capacitance C2, the current presently delivered by the battery I, the charge transfer voltage drop VRC1, the diffusion voltage drop VRC2, and the terminal voltage Vt. In another aspect, the second order equivalent circuit model may be employed in a forward mode to calculate an output voltage based on the input current, or in the reverse mode where an input voltage is provided in order to determine an output current as disclosed herein elsewhere.

In another aspect, the internal states VRC1 and VRC2 of the battery may be determined at 301 using the present current draw on the battery as input. As discussed herein elsewhere, the present current draw on the battery may be determined using a current sensor circuit that includes aspects such as a shunt resistor, Hall Effect sensor, and any other suitable current sensor. In another aspect, determining the present current draw on the battery may include measuring the current individually for one battery cell, for each separate battery cell in an array of multiple battery cells electrically connected together, and/or for multiple battery cells in an array electrically connected together and operating in the aggregate as a single battery.

At 302, the system determines calibration information, such as may be obtained using calibration module 104. A current limit may be determined at 303 such as by using the current limit module 105. A power limit is optionally determined at 304 by, for example, using the power module 106. The resulting charge or discharge current limit 102 and power limit 103 are the resulting final output. In another aspect, actions 301-304 may, where possible, be executed in parallel, sequentially, or in any combination thereof suitable for achieving the final result of obtaining the limits 102 and 103.

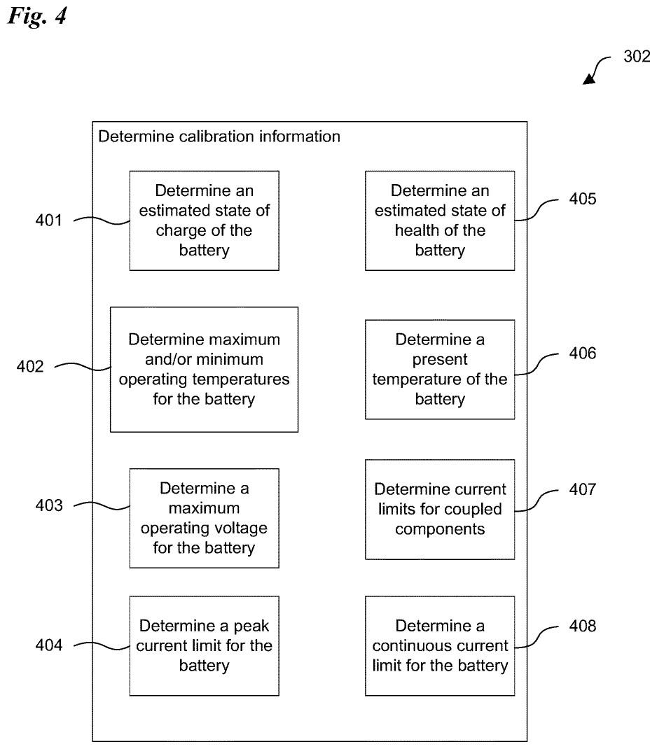

Illustrated in FIG. 4 is one example of actions the battery management system of the present disclosure may perform to determine calibration information (such as at 302 in FIG. 3). These actions, like others shown in the present disclosure, may be performed by any suitable module, device, circuit, processor, or control logic of the disclosed system, either implemented in hardware, or software, or any suitable combination thereof. The system may determine an estimated state of charge of the battery (401), the maximum and/or minimum operating temperatures for the battery (402), and/or the maximum operating voltage for the battery at 403. A peak current limit for the battery may be determined (404), an estimated state of health of the battery (405), and/or a present temperature of the battery at 406. Current limits for various components coupled to the battery management system or to the battery itself may be determined at 407. The continuous current limit for the battery may be determined at 408. The actions illustrated in FIG. 4 may be performed in any suitable sequential order, in parallel, or randomly in no particular order as needed. As disclosed herein, The system of the present disclosure may access this calibration information thus executing the disclosed actions as needed.

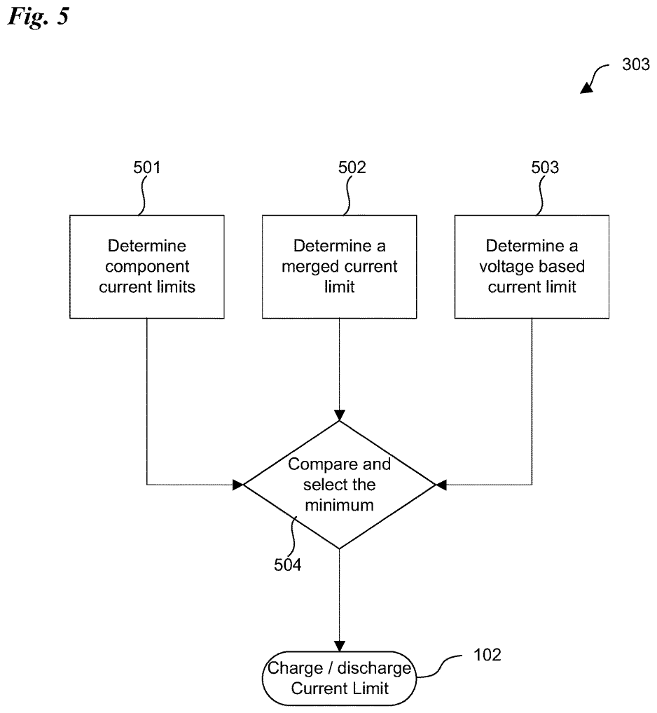

Illustrated in FIG. 5 is a flowchart illustrating at a high-level one example of actions the battery management system of the present disclosure may perform in order to determine the charge or discharge current limit 102 (such as at 303 in FIG. 3). At 501, the disclosed system optionally determines component current limits. These component current limits may be obtained in any suitable manner such as for example, by accessing aspects of the calibration information 109. These component current limits may include limits for components or devices or other aspects of the system that are electrically connected to the battery and therefore may be affected by the charge and discharge current or power. For example, component current limits may include limitations imposed by busbars, contactors, converters, inverters, the electric motor (or motors), connecting cables, or other aspects of the system, or of the environment the system is operating within.

At 502, the system optionally determines a merged current limit. The merged current limit, as disclosed herein elsewhere, optionally takes into consideration the peak and continuous current limits in relation to present loads on the battery in real time. The voltage based current limit may be completed at 503, and all three separate current limits determined at 501, 502, and 503 may be compared at 504 to determine an overall current limit. In one example, the overall current limit may be the minimum of these three separate current limits. The resulting current limit value may be used as the charge or discharge current limit 102.

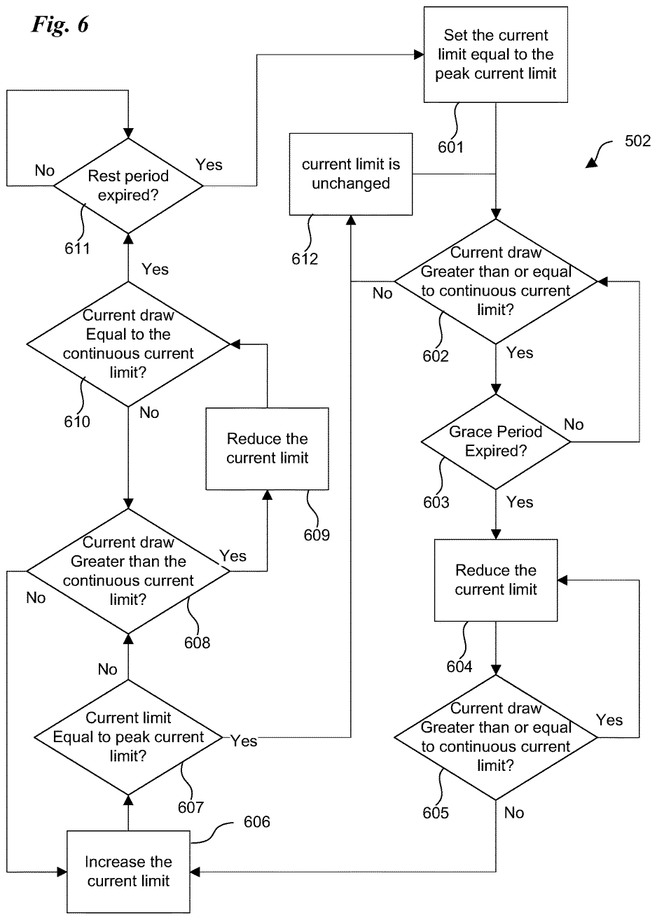

One example of actions the battery management system of the present disclosure may perform to determine a merged current limit (502) is shown in FIG. 6. In this example, the disclosed battery management system may be operable to determine a current limit that merges together aspects of the peak and continuous current limits specified by the battery cell manufacture thus allowing the battery to operate above the continuous current limit for a predetermined period of time followed by a predetermined rest period.

At 601, the battery management system optionally sets an initial working or applied current limit equal to the peak current limit for the battery. At 602, the system optionally determines whether the present current draw is greater than or equal to the continuous current limit. If not, the current limit remains unchanged at 612, and processing optionally continues to monitor whether or not the current draw on the battery is greater than or equal to the continuous current limit at 602. Thus while the present current draw on the battery is below the continuous current limit, the overall merged current limit optionally remains unchanged at the peak current value.

If the present current draw on the battery is greater than or equal to the continuous current limit for the battery at 602, the system optionally allows this situation to continue for a predetermined period of time, which may be referred to here as a “grace period”. This predetermined grace period may be less than one second, less than 10 seconds, less than a minute, less than five minutes, or five minutes or more. Any suitable grace period may be used. During the grace period, that is prior to its expiration, the disclosed system optionally continues to determine whether the present current draw on the battery is greater than or equal to the continuous current limit at 602. If during the grace period the present current draw on the battery falls below the continuous current limit, the grace period may be reset, the current limit may remain unchanged at 612, and the system may continue to monitor whether the present current draw on the battery is below the continuous current limit.

If the present current draw on the battery remains above the continuous current limit throughout the grace period, then at the expiration of the grace period at 603, the current limit may be reduced at 604, and the system optionally compares the present current draw with the continuous current limit at 605. If so, the system is operable to continue reducing the current limit at 604, and to continue comparing the present current draw with the continuous current limit at 605 until the present current draw is less than the continuous current limit.

This reduction may occur linearly, exponentially, geometrically, or according to any suitable approach. For example, the current limit may be reduced to the continuous current limit immediately (or as quickly as possible) upon expiration of the grace period. In another example, the current limit may be reduced incrementally in a linear fashion according to a predetermined reduction over a predetermined period of time, such as in the case of a predetermined number of amps with each execution of 604 and 605.

In another aspect, the rate of change of the reduction may be configurable in the control logic of the system and may be adjusted automatically with time as conditions change. For example, if the grace period rarely expires while the present current draw is greater than or equal to the continuous current limit, the initial rate of change may be linear and relatively slow (such as only a few milliamps per second). In another example, if the grace period begins to expire more often while the present current draw on the battery is greater than or equal to the continuous current limit, then the rate of change for the reduction of the current limit at 604 may become increasingly more rapid over time. This way the system optionally automatically adjusts the rate of change of the reduction as conditions change.

When the present current draw on the battery is less than the continuous current limit at 605, then the current limit may be increased at 606. As discussed above, this increase may be linear, exponential, geometric, and the like, and the rate of change may be fixed by the system, or may be automatically adjustable. When an increase in the current limit is made at 606, the system may compare the current limit with the peak current limit at 607. If equal, then the current limit optionally remains unchanged at the peak current limit, and processing continues at 612.

While the current limit has not yet reached the peak current limit at 607, the system optionally compares the present current draw on the battery with the continuous current limit to determine if the present current draw is greater at 608. If not, the current limit may be increased at 606 and processing continues at 607 with the comparison to the peak current limit. Thus at 606, 607, and 608, the system optionally raises the current limit to be equal to the peak current limit while the present current draw on the battery is less than the continuous current limit.

Another aspect, if the present current draw on the battery is greater than the continuous current limit at 608, the system optionally moves again to reduce the current limit at 609 following any suitable protocol process as discussed above such as linearly, exponentially, etc. At 610, the system may compare the present current draw on the battery with the continuous current limit. If the present current draw on the battery is not equal to the continuous current limit, then the system may be configured to determine whether the present current draw is greater than the continuous current limit. If not the current limit may be increased at 606, if so, the current limit may be reduced at 609. When the present current draw on the battery is equal to the continuous current limit at 610, the system optionally enters a rest period at 611. The rest period may be an optional predetermined period of time during which the current limit is maintained at the continuous current limit. This rest period may be provided to give the battery an opportunity to recover from a period of operation where the current drawn from the battery is above the continuous current limit but below the peak current limit (such as during the grace period discussed above). In this manner, the merged current limit may be useful to allow the system periods of operation above the continuous current limit followed by periods of rest such as may be useful for allowing the battery cells to cool down. When the rest period has expired at 611, the current limit may be set equal to the peak current limit at 601, and processing optionally continues as described above.

At any point in the process illustrated in FIG. 6, the current limit may be accessed by other aspects of the disclosed battery management system and/or provided as the merged current limit used by the system to determine the overall charge or discharge current limit 102. The process by which the merged current limit is determined may execute continuously, or be executed at repeated predetermined intervals. This predetermined interval is optionally a parameter that may be adjusted either manually by user input, or automatically by the system over time. For example, determining the merged current limit at 502 may be configured to execute less than once per second, every second, more than once per second, more than 10 times per second, more than 10,000 times per second, or more than 1 million times per second, to name a few nonlimiting examples.

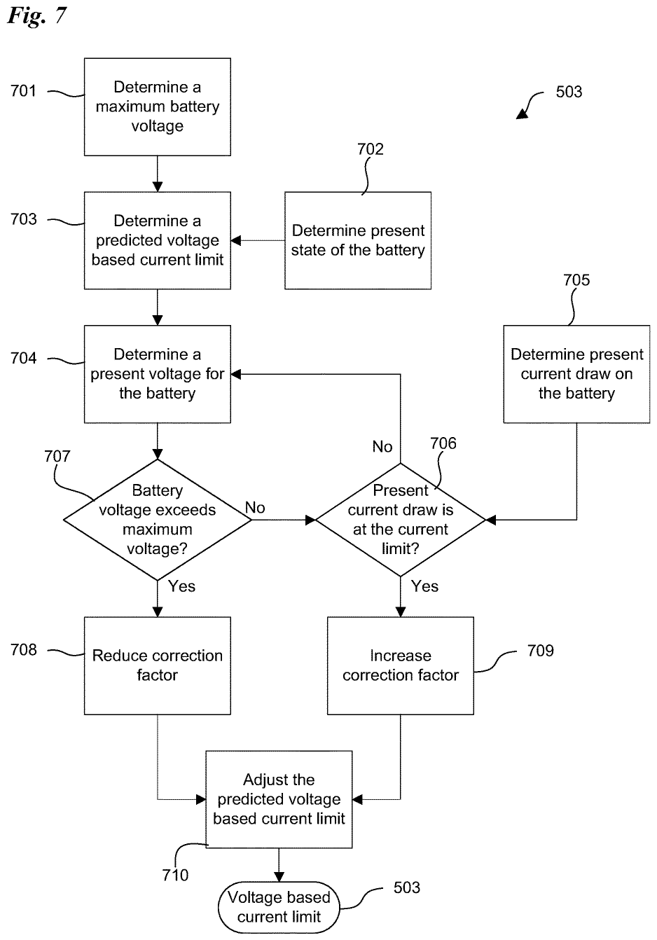

In another aspect, FIG. 7 illustrates one example of actions the battery management system of the present disclosure may perform to determine the voltage based current limit at 503. In one aspect, the system may be operable at 701 to determine a maximum battery voltage. In one example, the maximum battery voltage may be obtained from the calibration information 109. The state of the battery may be determined at 702. This optionally includes any suitable aspects of the battery such as may be determined using an equivalent circuit model like the one illustrated in FIG. 2. Present state of the battery may thus include VRC1, VRC2, and/or Vt, or other aspects that may be useful in determining a voltage based current limit. At 703, an initial predicted voltage based current limit is optionally determined. For example, the voltage based current limit may be determined using a second order equivalent circuit model operating in the reverse mode to calculate a current value that would cause the voltage Vt to reach the voltage operating limit for the battery, and to optionally avoid exceeding it.

To compensate for errors that may creep into equivalent circuit model calculations, a correction factor for the voltage based current limit may be calculated starting at 704. The system optionally determines at 704 the present voltage for the battery, such as by employing a voltage sensing circuit or other suitable voltage measurement. If the battery voltage exceeds the maximum voltage, the correction factor is reduced, perhaps to a value less than one, less than zero, or other value signifying that the predicted voltage based current limit calculated at 703 should be reduced. The resulting correction factor may then be applied to the voltage based current limit at 710 to achieve the overall result at 503.

If the battery voltage does not exceed the maximum voltage at 707, then the system may optionally determine if the present current draw is at the current limit for the battery at 706. If not, processing optionally continues at 704. The present current draw on the battery may be continuously monitored at 705 thus providing comparison input at 706. If the present current draw is at the current limit, the correction factor may be increased at 709 to a value greater than zero, greater than one, or some other value indicating that the initial predicted voltage based current limit could be raised. The resulting correction factor is optionally applied at 710 resulting in a voltage based current limit at 503.

Illustrated at 800 in FIG. 8 is one example of actions the battery management system of the present disclosure may perform to determine a charge or discharge power limit. At 801, the system optionally determines a predicted voltage when the battery operates at the charge or discharge current limit 102. A power limit may be determined at 802 using the current limit 102 and the predicted voltage from 801. The current limit 102 may be compared with the present current draw on the battery at 803, and the power limit from 802 is optionally compared with the present power output of the battery at 804. The predicted battery voltage is optionally adjusted at 805 to synchronize the power limit from 804 and the current limit from 803. An overall available power limit is optionally determined at 806 based on these values. The overall charge or discharge power limit 103 may, for example, be determined by multiplying the power limit available after 805 by the number of battery cells. This may be suitable in the instance where the system estimates the current and power limits by calculating the limits for a battery cell that is one of many similar or identical cells in a battery array. In another aspect, determining the overall power limit may involve no modification in the instance where the current and power limits are being calculated for a single battery. The result is that the power limit 103 is determined and is synchronized with the current limit 102. These current and power limits may then be provided as output to other devices or systems seeking to properly regulate their draw on the battery according to these limit values.

The battery management system of the present disclosure may be used with any suitable battery and irrespective of the operating environment. For example, the disclosed battery management system may be used in small batteries such as power tools, aerial vehicles such as helicopters, drones, or other aircraft, or in other installations such as in a car, truck, tractor, or other vehicle as part of a hybrid or electric drive system. The disclosed system is optionally advantageous for any battery, or group of batteries, particularly where it is preferable to be aware and responsive to the charge and discharge current power limits of the battery, and where it is preferable for the current and power limits to be synchronized.

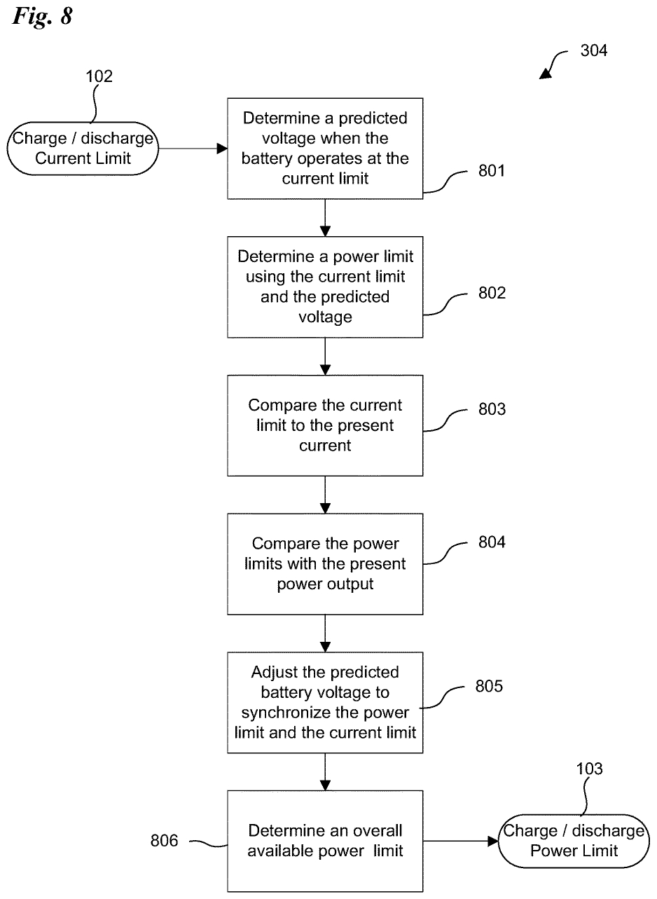

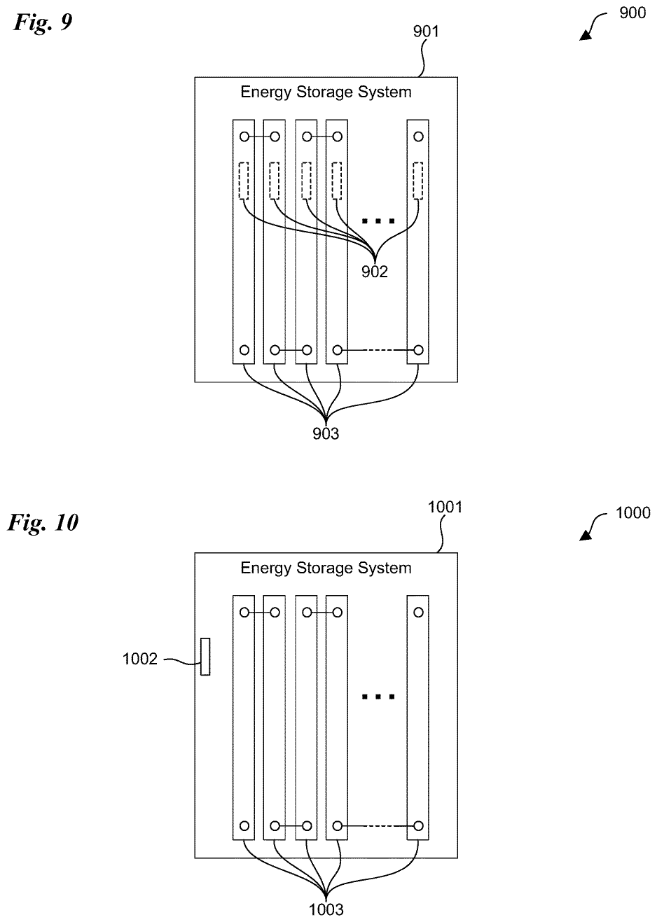

One example of the disclosed battery management system installed as part of an energy storage system is illustrated at 900 in FIG. 9. The energy storage system 901 includes multiple individual batteries, or battery cells, 903. In this example, the battery cells are electrically connected together in series, but other configurations may be used as well such as a parallel electrical connection, or combination of series and parallel connections.

In this instance, the disclosed battery management system 902 is optionally included separately in each individual battery cell. For example, the battery management system 902 may be implemented in hardware or software and positioned inside the housing of each of batteries 903 on a suitable substrate such as a PC board. The individual battery management system circuits 902 within each battery cell 903 may be configured to communicate with a control circuit of the energy storage system 901, or with other control circuits, so that batteries 903 may be responsive to the energy storage system via the disclosed battery management system 902.

In this configuration, each individual instance of the battery management system 902 is operable to manage the charge and discharge current and power limits as disclosed herein independently for each cell. The energy storage system 901 may access the charge and discharge current and power limits independently for each battery and use that information in order to manage the flow of power into and out of each cell while the energy storage system 901 is in use.

In another example, an energy storage system 1001 is illustrated in FIG. 10. In this instance, battery cells 1003 are electrically connected together in series (although any suitable electrical connection may be used). In this example, a single instance of the disclosed battery management system is included as part of energy storage system 1001. For example, the battery management system 1002 may be implemented in hardware or software and mounted to a PC board that is electrically connected to batteries 1003. The PC board may be mounted to the housing of the energy storage system 1001. In another example the energy storage system 1001 may include an energy storage system controller or other control circuitry, and the battery management system 1002 may be implemented in hardware, software, or any combination thereof, that is included in the control circuitry of the energy storage system 1001.

In this configuration, a single battery management system 1002 operates as disclosed herein to manage the charge and discharge current limits for the batteries 1003. The calculations and information collected and analyzed by the disclosed battery management system 1002 may optionally be made available to the energy storage system 1001, and possibly to other systems as well. In one aspect, the battery management system 1002 is optionally operable to consider batteries 1003 as a single battery and the calculations disclosed herein may be made for the battery cells 1003 in the aggregate rather than individually. In another aspect, the battery management system 1002 may be configured to determine the individual operating characteristics and calibration information of each individual cell, such as by polling the cells individually. This information may then be retained and recalled separately for each battery cell before making an overall determination of the charge and discharge current and power limits for energy storage system 1001.

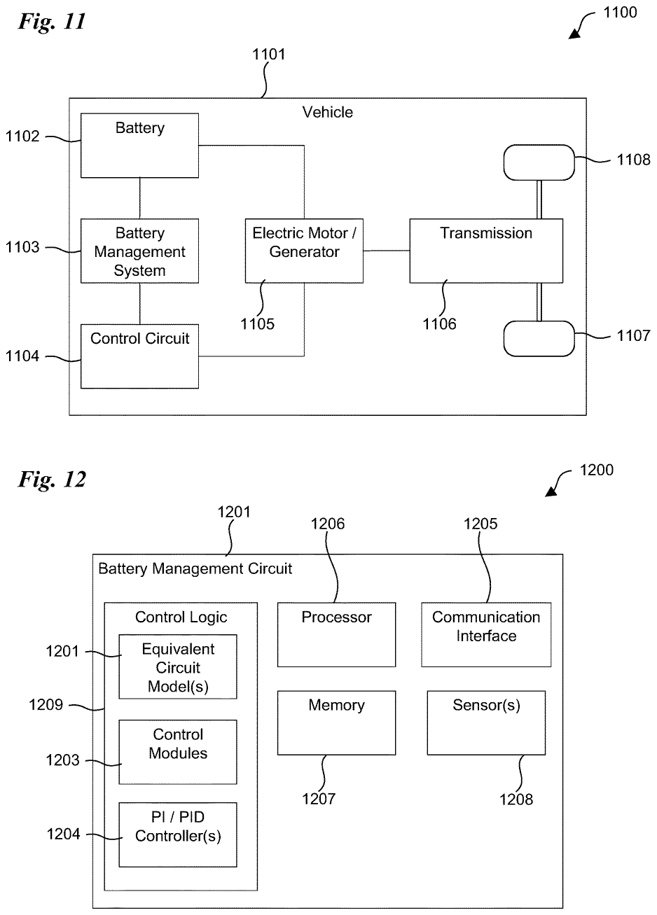

The disclosed battery management system may be included in a vehicle, such as a hybrid, or electric vehicle, one example of which is illustrated in FIG. 11 at 1100. Vehicle 1101 includes a battery 1102 that may be electrically connected or otherwise responsive to a battery management system 1103 according to the present disclosure. Battery 1102 may also be electrically connected to an electric motor generator 1105 arranged and configured to transfer power to one or more earth engaging elements 1107 and 1108 (such as tires, tracks, wheels, and the like). A transmission 1106 is optionally configured to adjust gear ratios between the electric motor generator 1105 and the earth engaging elements 1107 and 1108. They control circuit 1104 may be included for controlling the operation of the vehicle 1101. The battery management system 1103 may exchange information with control circuit 1104, and the electric motor generator 1105 may similarly send and receive information, instructions, data, and the like with control circuit 1104. Battery management system 1103 may be implemented according to any of the disclosed examples or aspects in order to manage the current and power limits, or other aspects of battery 1102.

The battery management system of the present disclosure may be implemented in a battery management circuit, one example of which is shown at 1200 in FIG. 12. In one example, battery management circuit 1201 includes control logic 1209. The control logic 1209 may be implemented in hardware including custom ASICs, FPGAs, or any suitable arrangement of logic gates, PI or PID controllers 1204, or other electronic components, operating using digital, analog, or other logic schemes, to implement the disclosed system and method. In another aspect, control logic 1209 may be implemented in software optionally stored in a memory 1207 and executed by a processor 1206. Control logic 1209 may include any control logic disclosed herein. For example, an equivalent circuit model 1201 may be implemented, as well as control modules 1203. One example of the equivalent circuit model 1201 is illustrated in FIG. 2 and discussed above.

Control logic 1209 may include multiple individual equivalent circuit models implemented in hardware or software and optionally optimized for particular purposes. For example, one equivalent circuit model may be configured to operate in the forward mode, while another may be configured to operate in the reverse mode. The inputs disclosed herein may be presented to the forward and reverse models as needed, and the outputs obtained. In another example, a single equivalent circuit model 1201 may be included in hardware or software and may be configurable to operate in either the forward or reverse mode as needed. In yet another example, multiple equivalent circuit models 1201 may be included, each configured to calculate values as disclosed herein separately and in parallel. In another example, equivalent circuit models 1201 and control modules 1203 may be implemented in software and may be configured to execute serially, in parallel, or any combination thereof, to expedite processing of the inputs to determine the charge and discharge power and current limits.

In another aspect, battery management circuit 1201 may include a communication interface 1205 for establishing and maintaining communication with other systems or resources external to the disclosed battery management system. These may include, but are not limited to, other controllers, or control circuits, which may provide information useful to the configuration, maintenance, operation, or other aspects, of the disclosed battery management system. Sensors 1208 may optionally be included in the battery management circuit 1201 to obtain information about the batteries useful to the disclosed system and method. In another example, one or more sensors may be included in an external system and not part of the battery management circuit 1201. These external sensors may be in communication with the battery management circuit 1201, such as by way of communication interface 1205.

The concepts illustrated and disclosed herein related to a battery management system may be arranged and configured according to any of the following non-limiting numbered examples:

Example 1: A power management system for a battery that is configured to estimate voltage states of the battery, and current and power limits of the battery.

Example 2: The system of any other example comprising a current module operable to determine the maximum available charge or discharge current of the battery.

Example 3: The system of any other example comprising a power module operable to determine the maximum available charge or discharge power of the battery.

Example 4: The system of any other example comprising a battery state module operable to determine the internal state of the battery.

Example 5: The system of any other example wherein the internal state of the battery includes an open circuit voltage VOC, and ohmic resistance of the battery R0, a charge transfer resistance R1, a charge transfer capacitance C1, a diffusion resistance R2, a diffusion capacitance C2, a current presently delivered by the battery I, a charge transfer voltage drop VRC1, a diffusion voltage drop VRC2, and a terminal voltage VT representing the potential difference across the battery that is presented to circuits electrically connected to the positive and negative battery terminals of the battery.

Example 6: The system of any other example wherein the ohmic resistance is the electronic and ionic resistances of the cell components such as the electrolyte conductivity, separator and electrical connections (terminals, current collectors, weld joints and contacts electrodes).

Example 7: The system of any other example wherein the charge transfer resistance is a resistance generated by the electrical chemical reactions in the electrodes.

Example 8: The system of any other example wherein the diffusion resistance as resistance caused by the localized increase/reduction of Li+ concentration in the electrode and electrolyte.

Example 9: The system of any other example wherein the battery includes a single battery cell.

Example 10: The system any other example wherein the battery includes multiple individual battery cells electrically connected together and operating as a battery module.

Example 11: The system of any other example wherein the voltage state includes the voltage potential across the battery with and without a load on the battery.

Example 12: The system of any other example wherein the current limits include a peak current limit representing the maximum possible current the battery can provide.

Example 13: The system of any other example wherein the current limits include a continuous current limit representing the maximum current the battery is rated to deliver over an extended period of time.

Example 14: The system of any other example wherein the system is configured to estimate the power limits of the battery.

Example 15: The system of any other example wherein the system is configured to synchronize current and power limits for the battery.

Example 16: The system of any other example wherein the disclosed power management system is optionally integrated into a PC board electrically connected to the battery.

Example 17: The system of any other example wherein multiple separate instances of the disclosed power management system are optionally integrated into a power distribution system electrically connected to the battery.

Example 18: The system of any other example wherein each individual battery cell is electrically connected to an individual power management circuit of the present disclosure in a battery module that includes multiple cells.

Example 19: The system of any other example wherein the disclosed power management system is optionally implemented as an electrical circuit that is included in an individual battery cell and is configured to monitor the disclosed aspects for that particular battery cell alone.

Example 20: The system of any other example wherein the disclosed power management system is optionally implemented as an electronic circuit that is included in a battery module having multiple individual battery cells, and the power management system is arranged and configured to monitor the disclosed aspects of each battery cell in the battery module.

Example 21: The system of any other example wherein the system is included as part of an energy storage system for a hybrid or electric vehicle, and wherein the battery, or batteries, monitored by the disclosed system are electrically connected to an electric motor of the hybrid or electric vehicle.

Example 22: The system of any other example wherein the battery is electrically connected to an electric motor.

Example 23: The system of any other example wherein the system is configured to determine aspects of the state of the battery based on the present current draw on the battery.

Example 24: The system of any other example wherein the system is configured to determine aspects of the state of the battery according to a second order equivalent circuit model.

Example 25: The system of any other example wherein the system is configured to determine the internal cells state of the battery VRC 1 and VRC 2.

Example 26: The system of any other example wherein the internal states of the battery VRC 1 and VRC 2 are calculated using the present current draw on the battery.

Example 27: The system of any other example wherein the present current draw on the battery is determined using a current sensor including, but not limited to, a shunt resistor, Hall Effect sensor, and the like.

Example 28: The system of any other example wherein the present current draw on the battery is determined individually for one battery cell, or for multiple battery cells electrically connected together and operating as a single battery module.

Example 29: The system of any other example wherein the system is configured to use a second order equivalent circuit model in a forward mode to calculate an output voltage based on the input current.

Example 30: The system of any other example wherein the system is configured to use a second order equivalent circuit model in a reverse mode where an input voltage is used to determine an output current.

Example 31: The system any other example wherein the system is configured to utilize a second order equivalent circuit model to determine a battery current draw that would cause the battery voltage to meet exceed a voltage operating limit for the battery.

Example 32: The system of any other example wherein the system includes calibration information about the battery.

Example 33: The system of any other example wherein calibration information includes maximum and minimum operating temperatures for the battery.

Example 34: The system of any other example wherein the system includes a temperature sensor arranged and configured to sense the present temperature of the battery.

Example 35: The system of any other example wherein calibration information includes a state of charge estimation.

Example 36: The system of any other example wherein the system is configured to determine an estimated state of charge of the battery.

Example 37: The system of any other example wherein the system is configured to optionally receive an estimated state of charge from an outside source.

Example 38: The system of any other example wherein calibration information includes a maximum operating cell voltage.

Example 39: The system of any other example wherein the calibration information includes component current limits specific to individual components electrically connected to the battery such as busbars, contactors, and the like.

Example 40: The system of any other example when the calibration information includes a peak current limit for the battery specifying the maximum instantaneous current that can be drawn from the battery at any given time.

Example 41: The system of any other example wherein the calibration information includes a continuous current limit specifying the maximum current that may be continuously drawn from the battery over an extended period of time.

Example 42: The system of any other example wherein the peak current limit is greater than the continuous current limit.

Example 43: The system of any other example wherein the peak current limit is determined based on the present battery temperature in the present battery state of charge

Example 44: The system of any other example wherein the calibration information is obtained by experimentation and/or is provided by the battery manufacturer and is optionally specific to each individual battery cell.

Example 45: The system of any other example wherein the system is configured to determine a merged current limit based on the peak current limit and the continuous current limit.

Example 46: The system of any other example wherein the current drawn by the battery is less than or equal to the merged current limit.

Example 47: The system of any other example wherein the system is configured to automatically adjust a merged current limit over time.

Example 48: The system of any other example wherein the merged current limit may be equal to the peak current limit for a predetermined grace period during which the merged current limit may be higher than the continuous current limit for the battery.

Example 49: The system of any other example wherein the merged current limit is automatically decreased over time after the grace period expires.

Example 50: The system of any other example wherein the merged current merged current limit is decreased linearly, geometrically, exponentially, or any combination thereof.

Example 51: The system of any other example where the merged current limit is automatically decreased when the merged current limit is greater than the continuous current limit.

Example 52: The system of any other example wherein the merged current limit is optionally increased to be greater than or equal to the continuous current limit when the present current drawn by the battery is less than the continuous current limit.

Example 53: The system of any other example wherein the merged current limit is optionally maintained at the continuous current limit for a predetermined rest period of time while the present current drawn by the battery is less than or equal to the continuous current limit and the merged current limit.

Example 54: The system of any other example wherein the merged current limit is optionally automatically adjusted toward the peak current limit after the rest period has expired.

Example 55: The system of any other example wherein the system is configured to determine a predicted voltage based current limit based on a maximum voltage limit.

Example 56: The system of any other example wherein the predicted voltage based current limit is calculated using a second order equivalent circuit model in the reverse mode.

Example 57: The system of any other example wherein the predicted voltage based current limit is determined by calculating what would be the current that makes the battery voltage to meet or exceed the voltage operating limit for the battery.

Example 58: The system of any other example wherein the predicted voltage based current limit is calculated according to the maximum operating voltage for the battery and/or the internal battery cell states VRC 1 and VRC 2.

Example 59: The system of any other example wherein the system is configured to determine a correction factor to be applied to the predicted voltage based current limit in order to obtain the voltage based current limit.

Example 60: The system of any other example wherein the correction factor for the predicted voltage based current limit is calculated according to the max operating voltage for the battery, and/or the present battery voltage.

Example 61: The system of any other example wherein the correction factor for the voltage based current limit is calculated using a PI and/or PID controller using a closed-loop control to address errors in the predicted voltage based current limit.

Example 62: The system of any other example wherein the voltage based current limit is determined using the predicted voltage based current limit and the correction factor.

Example 63: The system of any other example wherein the voltage based current limit is determined by multiplying the predicted voltage based current limit by the correction factor.

Example 64: The system of any other example wherein the correction factor is a number greater than zero and less than 2.0.

Example 65: The system of any other example wherein the current limit for charge or discharge of the battery is determined according to the voltage based current limit, the components current limit, and the merged current limit.

Example 66: The system of any other example wherein the current limit is the minimum of the voltage based current limit, the components current limit, and the merged current limit.

Example 67: The system of any other example wherein the system is configured to use a second order equivalent circuit model in a forward mode to determine a predicted battery voltage when the battery provides the current limit.

Example 68: The system of any other example wherein the system is configured to determine the predicted battery voltage according to the current limit and the present current draw on the battery.

Example 69: The system of any other example wherein the system is configured to determine a correction offset to apply to the predicted battery voltage to adjust for current limits and synchronize power and current limits.

Example 70: The system of any other example wherein the correction offset to apply to the predicted battery voltage is calculated according to the current limit, the present current draw on the battery, and the present power output of the battery.

Example 71: The system of any other example wherein the correction offset to apply to the predicted battery voltage is calculated using a PI and/or PID controller.

Example 72: The system of any other example wherein the system is configured to determine a power limit that is in sync with the current limit.

Example 73: The system of any other example wherein the power limit is calculated according to the current limit, the predicted battery voltage, and the predicted voltage correction offset.

Example 74: The system of any other example wherein the power limit is calculated by multiplying the current limit with the corrected predicted battery voltage.

Example 75: The system of any other example wherein the power limit is calculated by determining the power limits for one or more battery cells and combining them together.

The actions disclosed herein that may be included in a method of operating a battery management system of the present disclosure to determine current and power limits for one or more batteries may include any of the following non-limiting numbered examples:

Example 1: A method of estimating voltage, current, and/or power limits for a battery, or a collection of batteries operating in aggregate.

Example 2: The method of any other example comprising using a current module to determine the maximum available charge or discharge current of the battery.

Example 3: The method of any other example comprising using a power module to determine the maximum available charge or discharge power of the battery.

Example 4: The method of any other example comprising using a battery state module to determine the internal state of the battery.

Example 5: The method of any other example wherein the internal state of the battery includes an open circuit voltage VOC, an ohmic resistance of the battery R0, a charge transfer resistance R1, a charge transfer capacitance C1, a diffusion resistance R2, a diffusion capacitance C2, a current presently delivered by the battery I, a charge transfer voltage drop VRC1, a diffusion voltage drop VRC2, and a terminal voltage VT representing the potential difference across the battery that is presented to circuits electrically connected to the positive and negative battery terminals of the battery.

Example 6: The method of any other example wherein the ohmic resistance is the electronic and ionic resistances of the cell components such as the electrolyte conductivity, separator and electrical connections (terminals, current collectors, weld joints and contacts electrodes).

Example 7: The method of any other example wherein the charge transfer resistance is a resistance generated by the electrical chemical reactions in the electrodes.

Example 8: The method of any other example wherein the diffusion resistance is resistance caused by the localized increase/reduction of Li+ concentration in the electrode and electrolyte.

Example 9: The method of any other example wherein the battery includes a single battery cell.

Example 10: The method any other example wherein the battery includes multiple individual battery cells electrically connected together and operating as a battery module.

Example 11: The method of any other example wherein the voltage state includes the voltage potential across the battery with and without a load on the battery.

Example 12: The method of any other example wherein the current limits include a peak current limit representing the maximum possible current the battery can provide.

Example 13: The method of any other example wherein the current limits include a continuous current limit representing the maximum current the battery is rated to deliver over an extended period of time.

Example 14: The method of any other example wherein the system is configured to estimate the power limits of the battery.

Example 15: The method of any other example wherein the system is configured to synchronize current and power limits for the battery.

Example 16: The method of any other example comprising determining the internal state of the battery based on present current draw on the battery.

Example 17: The method of any other example comprising determining aspects of the state of the battery according to a second order equivalent circuit model.

Example 18: The method of any other example comprising determining the internal cells state of the battery VRC1 and VRC2.

Example 19: The method of any other example wherein the internal states of the battery VRC 1 and VRC 2 are calculated using the present current draw on the battery.

Example 20: The method of any other example wherein the present current draw on the battery is determined using a current sensor including, but not limited to, a shunt resistor, Hall Effect sensor, and the like.

Example 21: The method of any other example comprising determining present current draw on the battery individually for one battery cell, or for multiple battery cells electrically connected together and operating as a single battery module.

Example 22: The method of any other example comprising using a second order equivalent circuit model in a forward mode to calculate an output voltage based on the input current.

Example 23: The method of any other example comprising using a second order equivalent circuit model in a reverse mode where an input voltage is used to determine an output current.

Example 24: The method of any other example comprising using a second order equivalent circuit model to determine a battery current draw that would cause the battery voltage to meet exceed a voltage operating limit for the battery.

Example 25: The method of any other example comprising using calibration information about the battery to determine the current and power limits for the battery.

Example six: The method of any other example wherein the calibration information includes maximum and minimum operating temperatures for the battery.

Example 27: The method of any other example wherein the system includes a temperature sensor arranged and configured to sense the present temperature of the battery.

Example 28: The method of any other example wherein the calibration information includes a state of charge estimation.

Example 29: The method of any other example comprising determining an estimated state of charge of the battery.

Example 30: The method of any other example comprising determining an estimated state of charge using an outside source.

Example 31: The method of any other example wherein calibration information includes a maximum operating cell voltage.

Example 32: The method of any other example wherein the calibration information includes component current limits specific to individual components electrically connected to the battery such as busbars, contactors, and the like.

Example 33: The method of any other example when the calibration information includes a peak current limit for the battery specifying the maximum instantaneous current that can be drawn from the battery at any given time.

Example 34: The method of any other example wherein the calibration information includes a continuous current limit specifying the maximum current that may be continuously drawn from the battery over an extended period of time.

Example 35: The method of any other example wherein the peak current limit is greater than the continuous current limit.

Example 36: The method of any other example comprising determining the peak current limit based on the present battery temperature in the present battery state of charge

Example 37: The method any other example wherein the calibration information is obtained by experimentation and/or is provided by the battery manufacturer and is optionally specific to each individual battery cell.

Example 38: The method of any other example comprising determining a merged current limit based on the peak current limit and the continuous current limit.

Example 39: The method of any other example wherein the current drawn by the battery is less than or equal to the merged current limit.

Example 40: The method of any other example comprising automatically adjusting a merged current limit over time.

Example 41: The method of any other example wherein the merged current limit may be equal to the peak current limit for a predetermined grace period during which the merged current limit may be higher than the continuous current limit for the battery.

Example 42: The method of any other example comprising automatically decreasing the merged current limit over time after the grace period expires.

Example 43: The method of any other example comprising automatically decreasing the merged current limit over time linearly, geometrically, exponentially, or any combination thereof.

Example 44: The method of any other example comprising automatically decreasing the merged current limit when the merged current limit is greater than the continuous current limit.

Example 45: The method of any other example comprising automatically increasing the merged current limit to be greater than or equal to the continuous current limit when the present current drawn by the battery is less than the continuous current limit.

Example 46: The method of any other example comprising automatically maintaining the merged current limit at or about the continuous current limit for a predetermined rest period of time while the present current drawn by the battery is less than or equal to the continuous current limit and the merged current limit.

Example 47: The method of any other example comprising automatically adjusting the merged current limit toward the peak current limit after the rest period has expired.

Example 48: The method of any other example comprising determining a predicted voltage based current limit based on a maximum voltage limit.

Example 49: The method of any other example comprising calculating the voltage based current limit using a second order equivalent circuit model in the reverse mode.

Example 50: The method of any other example comprising determining predicted voltage based current limit by calculating what would be the current that makes the battery voltage reach or exceed the voltage operating limit for the battery.

Example 51: The method of any other example comprising determining the predicted voltage based current limit according to the maximum operating voltage for the battery and/or the internal battery cell states VRC 1 and VRC 2.

Example 52: The method of any other example comprising determining a correction factor to be applied to the predicted voltage based current limit in order to obtain the voltage based current limit.

Example 53: The method of any other example comprising calculating the correction factor for the predicted voltage based current limit according to the max operating voltage for the battery, and/or the present battery voltage.

Example 54: The method of any other example comprising determining the correction factor for the voltage based current using a PI and/or PID controller using a closed-loop control to address errors in the predicted voltage based current limit.

Example 55: The method of any other example comprising determining the voltage based current limit using the predicted voltage based current limit and the correction factor.

Example 56: The method of any other example comprising determining the voltage based current limit by multiplying the predicted voltage based current limit by the correction factor.

Example 57: The system of any other example wherein the correction factor is a number greater than zero and less than 2.0.

Example 58: The method of any other example comprising determining the current limit for charge or discharge of the battery according to the voltage based current limit, the components current limit, and the merged current limit.

Example 59: The method of any other example wherein the current limit is the minimum of the voltage based current limit, the components current limit, and the merged current limit.

Example 60: The method of any other example comprising determining a predicted battery voltage for a given current limit.

Example 61: The method of any other example comprising using a second order equivalent circuit model in a forward mode to determine a predicted battery voltage for a given current limit.

Example 62: The method of any other example comprising determining the predicted battery voltage according to the current limit and the present current draw on the battery.

Example 63: The method of any other example comprising determining a correction offset to apply to the predicted battery voltage to adjust for current limits and synchronize power and current limits.

Example 64: The method of any other example comprising determining the correction offset to apply to the predicted battery voltage according to the current limit, the present current draw on the battery, and the present power output of the battery.

Example 65: The method of any other example wherein the correction offset to apply to the predicted battery voltage is calculated using a PI and/or PID controller.

Example 66: The method of any other example comprising determining a power limit that is in sync with the current limit.

Example 67: The method of any other example comprising determining a power limit according to the current limit, the predicted battery voltage, and the predicted voltage correction offset.

Example 68: The method of any other example comprising determining a power limit by multiplying the current limit with the corrected predicted battery voltage.

Example 69: The method of any other example comprising comparing the current limit with a measured current.

Example 70: The method of any other example comprising comparing the power limit with a measured power.

Example 71: The method of any other example comprising determining power limits for one or more battery cells and combining them together.

### Glossary of Definitions and Alternatives

While the invention is illustrated in the drawings and described herein, this disclosure is to be considered as illustrative and not restrictive in character. The present disclosure is exemplary in nature and all changes, equivalents, and modifications that come within the spirit of the invention are included. The detailed description is included herein to discuss aspects of the examples illustrated in the drawings for the purpose of promoting an understanding of the principles of the invention. No limitation of the scope of the invention is thereby intended. Any alterations and further modifications in the described examples, and any further applications of the principles described herein are contemplated as would normally occur to one skilled in the art to which the invention relates. Some examples are disclosed in detail, however some features that may not be relevant may have been left out for the sake of clarity.

Where there are references to publications, patents, and patent applications cited herein, they are understood to be incorporated by reference as if each individual publication, patent, or patent application were specifically and individually indicated to be incorporated by reference and set forth in its entirety herein.

Singular forms “a”, “an”, “the”, and the like include plural referents unless expressly discussed otherwise. As an illustration, references to “a device” or “the device” include one or more of such devices and equivalents thereof.

Directional terms, such as “up”, “down”, “top” “bottom”, “fore”, “aft”, “lateral”, “longitudinal”, “radial”, “circumferential”, etc., are used herein solely for the convenience of the reader in order to aid in the reader's understanding of the illustrated examples. The use of these directional terms does not in any manner limit the described, illustrated, and/or claimed features to a specific direction and/or orientation.

Multiple related items illustrated in the drawings with the same part number which are differentiated by a letter for separate individual instances, may be referred to generally by a distinguishable portion of the full name, and/or by the number alone. For example, if multiple “laterally extending elements” 90A, 90B, 90C, and 90D are illustrated in the drawings, the disclosure may refer to these as “laterally extending elements 90A-90D,” or as “laterally extending elements 90,” or by a distinguishable portion of the full name such as “elements 90”.

The language used in the disclosure are presumed to have only their plain and ordinary meaning, except as explicitly defined below. The words used in the definitions included herein are to only have their plain and ordinary meaning. Such plain and ordinary meaning is inclusive of all consistent dictionary definitions from the most recently published Webster's and Random House dictionaries. As used herein, the following definitions apply to the following terms or to common variations thereof (e.g., singular/plural forms, past/present tenses, etc.):

“About” with reference to numerical values generally refers to plus or minus 10% of the stated value. For example, if the stated value is 4.375, then use of the term “about 4.375” generally means a range between 3.775 and 4.8125.

“Activate” generally is synonymous with “providing power to”, or refers to “enabling a specific function” of a circuit or electronic device that already has power.

“And/Or” generally refers to a grammatical conjunction indicating that one or more of the cases it connects may occur. For instance, it can indicate that either or both of two stated cases can occur. In general, “and/or” includes any combination of the listed collection. For example, “X, Y, and/or Z” encompasses: any one letter individually (e.g., {X}, {Y}, {Z}); any combination of two of the letters (e.g., {X, Y}, {X, Z}, {Y, Z}); and all three letters (e.g., {X, Y, Z}). Such combinations may include other unlisted elements as well.

“Battery” generally refers to an electrical energy storage device or storage system including multiple energy storage devices. A battery may include one or more separate electrochemical cells, each converting stored chemical energy into electrical energy by a chemical reaction to generate an electromotive force (or “EMF” measured in Volts). An individual battery cell may have a positive terminal (cathode) with a higher electrical potential, and a negative terminal (anode) that is at a lower electrical potential than the cathode. Any suitable electrochemical cell may be used that employ any suitable chemical process, including galvanic cells, electrolytic cells, fuel cells, flow cells and voltaic piles. When a battery is connected to an external circuit, electrolytes are able to move as ions within the battery, allowing the chemical reactions to be completed at the separate terminals thus delivering energy to the external circuit.

A battery may be a “primary” battery that can produce current immediately upon assembly. Examples of this type include alkaline batteries, nickel oxyhydroxide, lithium-copper, lithium-manganese, lithium-iron, lithium-carbon, lithium-thionyl chloride, mercury oxide, magnesium, zinc-air, zinc-chloride, or zinc-carbon batteries. Such batteries are often referred to as “disposable” insofar as they are generally not rechargeable and are discarded or recycled after discharge.

A battery may also be a “secondary” or “rechargeable” battery that can produce little or no current until charged. Examples of this type include lead-acid batteries, valve regulated lead-acid batteries, sealed gel-cell batteries, and various “dry cell” batteries such as nickel-cadmium (NiCd), nickel-zinc (NiZn), nickel metal hydride (NiMH), and lithium-ion (Li-ion) batteries.

“Capacitor” generally refers to a device that stores electrical energy. A capacitor generally includes one or more pairs of conductors separated by an insulator.

“Comparison Logic” generally refers to software or electronic circuits configured to compare two or more values and determine a result based on one or more rules. The rules may be encoded as software executed on a processor in a computer, or encoded by an arrangement of digital or analog logic gates or circuits. Examples include if-then decision trees, comparisons made based on the relationships between sets of values, decision logic implemented in a neural network, fuzzy logic for determine partial truth results, and the like.

“Communication Link” generally refers to a connection between two or more communicating entities for the purposes of passing information between the entities. The communication between the communicating entities may occur by any suitable means. For example the connection may be implemented as a physical link, an electrical link, an electromagnetic link, a logical link, or any other suitable linkage facilitating communication.

In the case of an electromagnetic link, the connection may be implemented by sending or receiving electromagnetic energy at any suitable frequency, thus allowing communications to pass as electromagnetic waves. These electromagnetic waves may or may not pass through a physical medium such as an optical fiber, or through free space via one or more sending and receiving antennas, or any combination thereof. Electromagnetic waves may be passed at any suitable frequency including any frequency in the electromagnetic spectrum.

A communication link may include any suitable combination of hardware which may include software components as well. Such hardware may include routers, switches, networking endpoints, repeaters, signal strength enters, hubs, and the like.

“Computer” or “Computing Device” generally refers to a device configured to compute a result based on input values or variables. A computer may include a processor for performing calculations to process input or output. A computer may include a memory for storing values to be processed by the processor, or for storing the results of previous processing.

A computer may also be configured to accept input and output from a wide array of input and output devices for receiving or sending values. Such devices include other computers, keyboards, mice, visual displays, printers, industrial equipment, and systems or machinery of all types and sizes. For example, a computer can control a network interface to perform various network communications upon request. The network interface may be part of the computer, or characterized as separate and remote from the computer.

A computer may be a single, physical, computing device such as a desktop computer, a laptop computer, or may be composed of multiple devices of the same type such as a group of servers operating as one device in a networked cluster, or a heterogeneous combination of different computing devices operating as one computer and linked together by a communication network. The communication network connected to the computer may also be connected to a wider network such as the Internet. Thus, a computer may include one or more physical processors or other computing devices or circuitry, and may also include any suitable type of memory.

A computer may also be a virtual computing platform having an unknown or fluctuating number of physical processors and memories or memory devices. A computer may thus be physically located in one geographical location or physically spread across several widely scattered locations with multiple processors linked together by a communication network to operate as a single computer.

The concept of “computer” and “processor” within a computer or computing device also encompasses any such processor or computing device serving to make calculations or comparisons as part of disclosed system. Processing operations related to threshold comparisons, rules comparisons, calculations, and the like occurring in a computer may occur, for example, on separate servers, the same server with separate processors, or on a virtual computing environment having an unknown number of physical processors as described above.

A computer may be optionally coupled to one or more visual displays and/or may include an integrated visual display. Likewise, displays may be of the same type, or a heterogeneous combination of different visual devices. A computer may also include one or more operator input devices such as a keyboard, mouse, touch screen, laser or infrared pointing device, or gyroscopic pointing device to name just a few representative examples. Also, besides a display, one or more other output devices may be included such as a printer, plotter, industrial manufacturing machine, 3D printer, and the like. As such, various display, input and output device arrangements are possible.

Multiple computers or computing devices may be configured to communicate with one another or with other devices over wired or wireless communication links to form a communication network. Network communications may pass through various computers operating as network appliances such as switches, routers, firewalls or other network devices or interfaces before passing over other larger computer networks such as the internet. Communications can also be passed over the communication network as wireless data transmissions carried over electromagnetic waves through transmission lines or free space. Such communications include using WiFi or other Wireless Local Area Network (WLAN) or a cellular transmitter/receiver to transfer data. Such signals conform to any of a number of wireless or mobile telecommunications technology standards such as 802.11a/b/g/n, 3G, 4G, 5G, and the like.

“Computer software”, or “Software” is an organized collection of bits representing computer instructions and data that tell the computer how to perform a series of actions. This is in contrast to physical hardware which is configured to actually perform the steps specified in the software. Examples include computer programs, libraries and related non-executable data, such as online documentation or digital media. Software includes processor specific instructions usually expressed as bits of binary data values signifying processor instructions that change the state of the computer from its preceding state. For example, an instruction may change the value stored in a particular storage location in the computer—an effect that is not directly observable to the user. An instruction may also invoke one of many input or output operations, for example displaying some text on a computer screen; causing state changes which should be visible to the user. The processor executes the instructions in the order they are provided, unless it is instructed to “jump” to a different instruction, or is interrupted by the operating system. As of 2015, most personal computers, smartphone devices and servers have processors with multiple execution units or multiple processors performing computation together, and computing has become a much more concurrent activity than in the past.

The majority of software is written in high-level programming languages. They are easier and more efficient for programmers because they are closer to natural languages than machine languages. High-level languages are translated into machine language using a compiler or an interpreter or a combination of the two. Software may also be written in a low-level assembly language, which has strong correspondence to the computer's machine language instructions and is translated into machine language using an assembler.

“Contact” generally refers to a condition and/or state where at least two objects are physically touching. For example, contact requires at least one location where objects are directly or indirectly touching, with or without any other member(s) material in between.

“Controller” or “Control Circuit” generally refers to a mechanical or electronic device configured to control the behavior of another mechanical or electronic device. A controller or a control circuit may be configured to provide signals or other electrical impulses that may be received and interpreted by the controlled device to indicate how it should behave. Controllers or control circuits may control other controllers or control circuits such as in a master-slave configuration where the master is configured to control a slave based on input from the master.

“Control Logic” generally refers to hardware or software configured to implement an automatic decision making process by which inputs are considered, and corresponding outputs are generated. The output may be used for any suitable purpose such as to provide specific commands to machines or processes specifying specific actions to take. Examples of control logic include computer programs executed by a processor to accept commands from a user and generate output according to the logic implemented in the program as executed by the processor. In another example, control logic may be implemented as a series of logic gates, microcontrollers, and the like, electrically connected together in a predetermined arrangement so as to accept input from other circuits or computers and produce an output according to the rules implemented in the logic circuits.

“Current” generally refers to the rate of flow of electric charge past a point or region of an electric circuit. An electric current is said to exist when there is a net flow of electric charge through a region.

“Data” generally refers to one or more values of qualitative or quantitative variables that are usually the result of measurements. Data may be considered “atomic” as being finite individual units of specific information. Data can also be thought of as a value or set of values that includes a frame of reference indicating some meaning associated with the values. For example, the number “2” alone is a symbol that absent some context is meaningless. The number “2” may be considered “data” when it is understood to indicate, for example, the number of floors in a house.

Data may be organized and represented in a structured format. Examples include a tabular representation using rows and columns, a tree representation with a set of nodes considered to have a parent-children relationship, or a graph representation as a set of connected nodes to name a few.

The term “data” can refer to unprocessed data or “raw data” such as a collection of numbers, characters, or other symbols representing individual facts or opinions. Data may be collected by sensors in controlled or uncontrolled environments, or generated by observation, recording, or by processing of other data. The word “data” may be used in a plural or singular form. The older plural form “datum” may be used as well.

“Database” also referred to as a “data store”, “data repository”, or “knowledge base” generally refers to an organized collection of data. The data is typically organized to model aspects of the real world in a way that supports processes obtaining information about the world from the data. Access to the data is generally provided by a “Database Management System” (DBMS) consisting of an individual computer software program or organized set of software programs that allow user to interact with one or more databases providing access to data stored in the database (although user access restrictions may be put in place to limit access to some portion of the data). The DBMS provides various functions that allow entry, storage and retrieval of large quantities of information as well as ways to manage how that information is organized. A database is not generally portable across different DBMSs, but different DBMSs can interoperate by using standardized protocols and languages such as Structured Query Language (SQL), Open Database Connectivity (ODBC), Java Database Connectivity (JDBC), or Extensible Markup Language (XML) to allow a single application to work with more than one DBMS.

Databases and their corresponding database management systems are often classified according to a particular database model they support. Examples include a DBMS that relies on the “relational model” for storing data, usually referred to as Relational Database Management Systems (RDBMS). Such systems commonly use some variation of SQL to perform functions which include querying, formatting, administering, and updating an RDBMS. Other examples of database models include the “object” model, the “object-relational” model, the “file”, “indexed file” or “flat-file” models, the “hierarchical” model, the “network” model, the “document” model, the “XML” model using some variation of XML, the “entity-attribute-value” model, and others.

Examples of commercially available database management systems include PostgreSQL provided by the PostgreSQL Global Development Group; Microsoft SQL Server provided by the Microsoft Corporation of Redmond, Washington, USA; MySQL and various versions of the Oracle DBMS, often referred to as simply “Oracle” both separately offered by the Oracle Corporation of Redwood City, California, USA; the DBMS generally referred to as “SAP” provided by SAP SE of Walldorf, Germany; and the DB2 DBMS provided by the International Business Machines Corporation (IBM) of Armonk, New York, USA.

The database and the DBMS software may also be referred to collectively as a “database”. Similarly, the term “database” may also collectively refer to the database, the corresponding DBMS software, and a physical computer or collection of computers. Thus the term “database” may refer to the data, software for managing the data, and/or a physical computer that includes some or all of the data and/or the software for managing the data.

“Electric Motor” generally refers to an electrical machine that converts electrical energy into mechanical energy. Normally, but not always, electric motors operate through the interaction between one or more magnetic fields in the motor and winding currents to generate force in the form of rotation. Electric motors can be powered by direct current (DC) sources, such as from batteries, motor vehicles, and/or rectifiers, or by alternating current (AC) sources, such as a power grid, inverters, and/or electrical generators. An electric generator can (but not always) be mechanically identical to an electric motor, but operate in the reverse direction, accepting mechanical energy and converting the mechanical energy into electrical energy.

“Electrical Connection” means here a connection between two objects that allows a flow of electric current and/or electric signals.

“Electrically Connected” generally refers to a configuration of two objects that allows electricity to flow between them or through them. In one example, two conductive materials are physically adjacent one another and are sufficiently close together so that electricity can pass between them. In another example, two conductive materials are in physical contact allowing electricity to flow between them.

“Energy Source” generally refers to a device, structure, mechanism, and/or system that provides power for performing work. The energy supplied by the energy source can take many forms including electrical, chemical, electrochemical, nuclear, hydraulic, pneumatic, gravitational, kinetic, and/or potential energy forms. The energy source for instance can include ambient energy sources, such as solar panels, external energy sources, such as from electrical power transmission networks, and/or portable energy sources, such as batteries. The energy source can include an energy carrier containing energy that can be later converted to other forms, such as into mechanical, heat, electrical, and/or chemical forms. Energy carriers can for instance include springs, electrical batteries, capacitors, pressurized air, dammed water, hydrogen, petroleum, coal, wood, and/or natural gas, to name just a few.

“Interchangeable” generally refers to two or more things that are capable of being put and/or used in place of each other. In other words, one thing is capable of replacing and/or changing places with something else. For example, interchangeable parts typically, but not always, are manufactured to have nearly the same structural size as well as shape within normal manufacturing tolerances and have nearly the same operational characteristics so that one part can be replaced by another interchangeable part. In some cases, the interchangeable parts can be manufactured and/or sold by a specific company under the same part or Stock Keeping Unit (SKU) identifier, and in other cases, different companies can manufacture and/or sell the same interchangeable parts.

Impedance” generally refers to the opposition to alternating current presented by the combined effect of resistance and reactance in a circuit.

“Lateral” generally refers to being situated on, directed toward, or coming from the side.

“Longitudinal” generally relates to length or lengthwise dimension of an object, rather than across.

“Means For” in a claim invokes 35 U.S.C. 112(f), literally encompassing the recited function and corresponding structure and equivalents thereto. Its absence does not, unless there otherwise is insufficient structure recited for that claim element. Nothing herein or elsewhere restricts the doctrine of equivalents available to the patentee.

“Memory” generally refers to any storage system or device configured to retain data or information. Each memory may include one or more types of solid-state electronic memory, magnetic memory, or optical memory, just to name a few. Memory may use any suitable storage technology, or combination of storage technologies, and may be volatile, nonvolatile, or a hybrid combination of volatile and nonvolatile varieties. By way of non-limiting example, each memory may include solid-state electronic Random Access Memory (RAM), Sequentially Accessible Memory (SAM) (such as the First-In, First-Out (FIFO) variety or the Last-In-First-Out (LIFO) variety), Programmable Read Only Memory (PROM), Electronically Programmable Read Only Memory (EPROM), or Electrically Erasable Programmable Read Only Memory (EEPROM).

Memory can refer to Dynamic Random Access Memory (DRAM) or any variants, including static random access memory (SRAM), Burst SRAM or Synch Burst SRAM (BSRAM), Fast Page Mode DRAM (FPM DRAM), Enhanced DRAM (EDRAM), Extended Data Output RAM (EDO RAM), Extended Data Output DRAM (EDO DRAM), Burst Extended Data Output DRAM (BEDO DRAM), Single Data Rate Synchronous DRAM (SDR SDRAM), Double Data Rate SDRAM (DDR SDRAM), Direct Rambus DRAM (DRDRAM), or Extreme Data Rate DRAM (XDR DRAM).

Memory can also refer to non-volatile storage technologies such as Non-Volatile Read Access memory (NVRAM), flash memory, non-volatile Static RAM (nvSRAM), Ferroelectric RAM (FeRAM), Magnetoresistive RAM (MRAM), Phase-change memory (PRAM), Conductive-Bridging RAM (CBRAM), Silicon-Oxide-Nitride-Oxide-Silicon (SONOS), Resistive RAM (RRAM), Domain Wall Memory (DWM) or “Racetrack” memory, Nano-RAM (NRAM), or Millipede memory. Other non-volatile types of memory include optical disc memory (such as a DVD or CD ROM), a magnetically encoded hard disc or hard disc platter, floppy disc, tape, or cartridge media. The concept of a “memory” includes the use of any suitable storage technology or any combination of storage technologies.

“Microcontroller” or “MCU” generally refers to a small computer on a single integrated circuit. It may be similar to, but less sophisticated than, a System on a Chip or “SoC”; an SoC may include a microcontroller as one of its components. A microcontroller may contain one or more CPUs (processor cores) along with memory and programmable input/output peripherals. Program memory in the form of ferroelectric RAM, NOR flash or OTP ROM may also be included on the chip, as well as a small amount of RAM. Microcontrollers may be designed for embedded applications, in contrast to the microprocessors used in personal computers or other general purpose applications consisting of various discrete chips.

Microcontrollers may be included in automatically controlled products and devices, such as automobile engine control systems, implantable medical devices, remote controls, office machines, appliances, power tools, toys and other embedded systems. An MCU may be configured to handle mixed signals thus integrating analog components needed to control non-digital electronic systems.

Some microcontrollers may use four-bit words and operate at frequencies as low as 4 kHz, for low power consumption (single-digit milliwatts or microwatts). They will generally have the ability to retain functionality while waiting for an event such as a button press or other interrupt; power consumption while sleeping (CPU clock and most peripherals off) may be just nanowatts, making many of them well suited for long lasting battery applications. Other microcontrollers may serve performance roles, where they may need to act more like a Digital Signal Processor (DSP), with higher clock speeds and power consumption. A micro-controller may include any suitable combination of circuits such as:
1. a central processing unit—ranging from small and simple processors with registers as small as 4 bits or list, to complex processors with registers that are 32, 64, or more bits
2. volatile memory (RAM) for data storage
3. ROM, EPROM, EEPROM or Flash memory for program and operating parameter storage
4. discrete input and output bits, allowing control or detection of the logic state of an individual package pin
5. serial input/output such as serial ports (UARTs)
6. other serial communications interfaces like I²C, Serial Peripheral Interface and Controller Area Network for system interconnect
7. peripherals such as timers, event counters, PWM generators, and watchdog
8. clock generator—often an oscillator for a quartz timing crystal, resonator or RC circuit
9. many include analog-to-digital converters, some include digital-to-analog converters
10. in-circuit programming and in-circuit debugging support.

“Module” or “Engine” generally refers to a collection of computational or logic circuits implemented in hardware, or to a series of logic or computational instructions expressed in executable, object, or source code, or any combination thereof, configured to perform tasks or implement processes. A module may be implemented in software maintained in volatile memory in a computer and executed by a processor or other circuit. A module may be implemented as software stored in an erasable/programmable nonvolatile memory and executed by a processor or processors. A module may be implanted as software coded into an Application Specific Information Integrated Circuit (ASIC). A module may be a collection of digital or analog circuits configured to control a machine and/or to generate a desired outcome.

Modules may be executed on a single computer with one or more processors, or by multiple computers with multiple processors coupled together by a network. Separate aspects, computations, or functionality performed by a module may be executed by separate processors on separate computers, by the same processor on the same computer, or by different computers at different times.

“Motor” generally refers to a machine that supplies motive power for a device with moving parts. The motor can include rotor and linear type motors. The motor can be powered in any number of ways, such as via electricity, internal combustion, pneumatics, and/or hydraulic power sources. By way of non-limiting examples, the motor can include a servomotor, a pneumatic motor, a hydraulic motor, a steam engine, pneumatic piston, hydraulic piston, and/or an internal combustion engine.

“Multiple” as used herein is synonymous with the term “plurality” and refers to more than one, or by extension, two or more.

“Network” or “Computer Network” generally refers to a telecommunications network that allows computers to exchange data. Computers can pass data to each other along data connections by transforming data into a collection of datagrams or packets. The connections between computers and the network may be established using either cables, optical fibers, or via electromagnetic transmissions such as for wireless network devices.

Computers coupled to a network may be referred to as “nodes” or as “hosts” and may originate, broadcast, route, or accept data from the network. Nodes can include any computing device such as personal computers, phones, and servers as well as specialized computers that operate to maintain the flow of data across the network, referred to as “network devices”. Two nodes can be considered “networked together” when one device is able to exchange information with another device, whether or not they have a direct connection to each other.

Examples of wired network connections may include Digital Subscriber Lines (DSL), coaxial cable lines, or optical fiber lines. The wireless connections may include BLUETOOTH®, Worldwide Interoperability for Microwave Access (WiMAX), infrared channel or satellite band, or any wireless local area network (Wi-Fi) such as those implemented using the Institute of Electrical and Electronics Engineers' (IEEE) 802.11 standards (e.g. 802.11(a), 802.11(b), 802.11(g), or 802.11(n) to name a few). Wireless links may also include or use any cellular network standards used to communicate among mobile devices including 1G, 2G, 3G, or 4G. The network standards may qualify as 1G, 2G, etc. by fulfilling a specification or standards such as the specifications maintained by the International Telecommunication Union (ITU). For example, a network may be referred to as a “3G network” if it meets the criteria in the International Mobile Telecommunications-2000 (IMT-2000) specification regardless of what it may otherwise be referred to. A network may be referred to as a “4G network” if it meets the requirements of the International Mobile Telecommunications Advanced (IMTAdvanced) specification. Examples of cellular network or other wireless standards include AMPS, GSM, GPRS, UMTS, LTE, LTE Advanced, Mobile WiMAX, and WiMAX-Advanced.

Cellular network standards may use various channel access methods such as FDMA, TDMA, CDMA, or SDMA. Different types of data may be transmitted via different links and standards, or the same types of data may be transmitted via different links and standards.

The geographical scope of the network may vary widely. Examples include a Body Area Network (BAN), a Personal Area Network (PAN), a Local-Area Network (LAN), a Metropolitan Area Network (MAN), a Wide Area Network (WAN), or the Internet.

A network may have any suitable network topology defining the number and use of the network connections. The network topology may be of any suitable form and may include point-to-point, bus, star, ring, mesh, or tree. A network may be an overlay network which is virtual and is configured as one or more layers that use or “lay on top of” other networks.

A network may utilize different communication protocols or messaging techniques including layers or stacks of protocols. Examples include the Ethernet protocol, the internet protocol suite (TCP/IP), the ATM (Asynchronous Transfer Mode) technique, the SONET (Synchronous Optical Networking) protocol, or the SDE1 (Synchronous Digital Elierarchy) protocol. The TCP/IP internet protocol suite may include the application layer, transport layer, internet layer (including, e.g., IPv6), or link layer.

“Of the present disclosure” generally refers to any example of a concept sharing the same or similar name that is included in the chain of priority of the present application, or that is included by reference, if such inclusion is permitted and is applicable. For example, a “system of the present disclosure” refers to any example, or combination or permutation of features, of a system presented herein.

“Optionally” means discretionary; not required; possible, but not compulsory; left to personal choice.

“Portion” means a part of a whole, either separated from or integrated with it.

“Positive Clutch” generally refers to a type of clutch that is designed to transmit torque without slippage such as through a mechanical interference type connection. Some examples of positive clutches include jaw clutches (e.g., square or spiral jaw clutches) and dog clutches.

“Powertrain” generally refers to devices and/or systems used to transform stored energy into kinetic energy for propulsion purposes. The powertrain can include multiple power sources and can be used in non-wheel-based vehicles. By way of non-limiting examples, the stored energy sources can include chemical, solar, nuclear, electrical, electrochemical, kinetic, and/or other potential energy sources. For example, the powertrain in a motor vehicle includes the devices that generate power and deliver the power to the road surface, water, and/or air. These devices in the powertrain include engines, motors, transmissions, drive shafts, differentials, and/or final drive components (e.g., drive wheels, continuous tracks, propeller, thrusters, etc.).

“Predominately” as used herein is synonymous with greater than 50%.

“Processor” generally refers to one or more electronic components configured to operate as a single unit configured or programmed to process input to generate an output. Alternatively, when of a multi-component form, a processor may have one or more components located remotely relative to the others. One or more components of each processor may be of the electronic variety defining digital circuitry, analog circuitry, or both. In one example, each processor is of a conventional, integrated circuit microprocessor arrangement, such as one or more PENTIUM, i3, i5 or i7 processors supplied by INTEL Corporation of 2200 Mission College Boulevard, Santa Clara, Calif. 95052, USA. In another example, the processor uses a Reduced Instruction Set Computing (RISC) architecture, such as an Advanced RISC Machine (ARM) type processor developed and licensed by ARM Holdings of Cambridge, United Kingdom. In still yet other examples, the processor can include a Central Processing Unit (CPU) and/or an Accelerated Processing Unit (APU), such as those using a K8, K10, Bulldozer, Bobcat, Jaguar, and Zen series architectures, supplied by Advanced Micro Devices, Inc. (AMD) of Santa Clara, California.

Another example of a processor is an Application-Specific Integrated Circuit (ASIC). An ASIC is an Integrated Circuit (IC) customized to perform a specific series of logical operations for controlling the computer to perform specific tasks or functions. An ASIC is an example of a processor for a special purpose computer, rather than a processor configured for general-purpose use. An application-specific integrated circuit generally is not reprogrammable to perform other functions and may be programmed once when it is manufactured.

In another example, a processor may be of the “field programmable” type. Such processors may be programmed multiple times “in the field” to perform various specialized or general functions after they are manufactured. A field-programmable processor may include a Field-Programmable Gate Array (FPGA) in an integrated circuit in the processor. FPGA may be programmed to perform a specific series of instructions which may be retained in nonvolatile memory cells in the FPGA. The FPGA may be configured by a customer or a designer using a Hardware Description Language (HDL). An FPGA may be reprogrammed using another computer to reconfigure the FPGA to implement a new set of commands or operating instructions. Such an operation may be executed in any suitable means such as by a firmware upgrade to the processor circuitry.

Just as the concept of a computer is not limited to a single physical device in a single location, so also the concept of a “processor” is not limited to a single physical logic circuit or package of circuits but includes one or more such circuits or circuit packages possibly contained within or across multiple computers in numerous physical locations. In a virtual computing environment, an unknown number of physical processors may be actively processing data, and the unknown number may automatically change over time as well.

The concept of a “processor” includes a device configured or programmed to make threshold comparisons, rules comparisons, calculations, or perform logical operations applying a rule to data yielding a logical result (e.g. “true” or “false”). Processing activities may occur in multiple single processors on separate servers, on multiple processors in a single server with separate processors, or on multiple processors physically remote from one another in separate computing devices.

“Reactance” generally refers to the opposition presented to current by inductance and/or capacitance. For example, a greater reactance gives a smaller current value per the same applied voltage.

“Resistance” generally refers to a measure of the opposition to current flow in an electrical circuit. Resistance is generally expressed in Ohms.

“Resistor” means a device having a resistance to the passage of electrical current.

“Resistor-Capacitor Circuit” generally refers to a circuit with one or more resistors and one or more capacitors.

“Rule” generally refers to a conditional statement with at least two outcomes. A rule may be compared to available data, which can yield a positive result (all aspects of the conditional statement of the rule are satisfied by the data), or a negative result (at least one aspect of the conditional statement of the rule is not satisfied by the data). One example of a rule is shown below as pseudo code of an “if/then/else” statement that may be coded in a programming language and executed by a processor in a computer:

| if | (clouds.areGrey( ) and (clouds.numberOfClouds > 100) ) then | |
|---|---|---|
| | { | |
| | | prepare for rain; |
| | } | else { |
| | | Prepare for sunshine; |

}

“Sensor” generally refers to a transducer configured to sense or detect a characteristic of the environment local to the sensor. For example, sensors may be constructed to detect events or changes in quantities or sensed parameters providing a corresponding output, generally as an electrical or electromagnetic signal. A sensor's sensitivity indicates how much the sensor's output changes when the input quantity being measured changes.

“Sense parameter” generally refers to a property of the environment detectable by a sensor. As used herein, sense parameter can be synonymous with an operating condition, environmental factor, sensor parameter, or environmental condition. Sense parameters may include temperature, air pressure, speed, acceleration, the presence or intensity of sound or light or other electromagnetic phenomenon, the strength and/or orientation of a magnetic or electrical field, and the like.

“Series” means an electrical connection of two or more components where current passes through the first component and into the second component, and where the current passing through the two components is the same.

“State” generally refers to the particular condition that someone or something is in at a specific time.

“Substantially” generally refers to the degree by which a quantitative representation may vary from a stated reference without resulting in an essential change of the basic function of the subject matter at issue. The term “substantially” is utilized herein to represent the inherent degree of uncertainty that may be attributed to any quantitative comparison, value, measurement, and/or other representation.

“Transmission” generally refers to a power system that provides controlled application of mechanical power. The transmission uses gears and/or gear trains to provide speed, direction, and/or torque conversions from a rotating power source to another device.

“Transverse” generally refers to things, axes, straight lines, planes, or geometric shapes extending in a non-parallel and/or crosswise manner relative to one another. For example, when in a transverse arrangement, lines can extend at right angles or perpendicular relative to one another, but the lines can extend at other non-straight angles as well such as at acute, obtuse, or reflex angles. For instance, transverse lines can also form angles greater than zero (0) degrees such that the lines are not parallel. When extending in a transverse manner, the lines or other things do not necessarily have to intersect one another, but they can.

“Triggering a Rule” generally refers to an outcome that follows when all elements of a conditional statement expressed in a rule are satisfied. In this context, a conditional statement may result in either a positive result (all conditions of the rule are satisfied by the data), or a negative result (at least one of the conditions of the rule is not satisfied by the data) when compared to available data. The conditions expressed in the rule are triggered if all conditions are met causing program execution to proceed along a different path than if the rule is not triggered.

“Vehicle” generally refers to a machine that transports people and/or cargo. Common vehicle types can include land based vehicles, amphibious vehicles, watercraft, aircraft, and space craft. By way of non-limiting examples, land based vehicles can include wagons, carts, scooters, bicycles, motorcycles, automobiles, buses, trucks, semi-trailers, trains, trolleys, and trams. Amphibious vehicles can for example include hovercraft and duck boats, and watercraft can include ships, boats, and submarines, to name just a few examples. Common forms of aircraft include airplanes, helicopters, autogiros, and balloons, and spacecraft for instance can include rockets and rocket-powered aircraft. The vehicle can have numerous types of power sources. For instance, the vehicle can be powered via human propulsion, electrically powered, powered via chemical combustion, nuclear powered, and/or solar powered. The direction, velocity, and operation of the vehicle can be human controlled, autonomously controlled, and/or semi-autonomously controlled. Examples of autonomously or semi-autonomously controlled vehicles include Automated Guided Vehicles (AGVs) and drones.

What is claimed is:

1. A method comprising:
determining an internal state of a battery based on a present current draw on the battery according to a first stage equivalent circuit model implemented in a battery management circuit;
determining a predicted voltage based current limit based on a maximum voltage limit for the battery according to a second stage equivalent circuit model implemented in the battery management circuit;
determining a current limit correction factor to be applied to the predicted voltage based current limit using the battery management circuit;
determining a voltage based current limit by combining the predicted voltage based current limit and the correction factor using the battery management circuit;
determining a current limit for charge or discharge of the battery according to the voltage based current limit, a peak current limit, and a continuous current limit using the battery management circuit;
determining an expected voltage based on the current limit using the battery management circuit; and
determining an available power output based on the current limit and the expected voltage using the battery management circuit.

2. The method of claim 1, wherein determining an expected voltage comprises:
determining a predicted battery voltage based on the current limit and the internal state of the battery according to a third stage equivalent circuit model implemented in the battery management circuit; and
combining the predicted battery voltage and a correction offset to determine the expected voltage using the battery management circuit.

3. The method of claim 1, wherein determining an available power output comprises:
calculating a power limit by multiplying the battery current limit and the expected voltage using the battery management circuit.

4. The method of claim 1, comprising:
determining calibration information about the battery using the battery monitoring circuit.

5. The method of claim 4, wherein determining the calibration information comprises any combination of:
determining an estimated state of charge of the battery;
determining maximum and minimum operating temperatures for the battery; and
determining a maximum operating voltage for the battery.

6. The method of claim 4, wherein determining the calibration information comprises any combination of:
determining a peak current limit specifying a maximum instantaneous current that can be drawn from the battery; and
determining a continuous current limit specifying a maximum current that may be continuously drawn from the battery over a specified period of time.

7. The method of claim 1, wherein determining the current limit for charge or discharge of the battery comprises:
determining a merged current limit based on the peak current limit and the continuous current limit using the battery monitoring circuit, wherein the battery monitoring circuit automatically adjusts the merged current limit according to the present current draw on the battery.

8. The method of claim 7, wherein the merged current limit may be equal to the peak current limit for a predetermined grace period during which the merged current limit may be higher than the continuous current limit of the battery.

9. The method of claim 8, comprising:
decreasing the merged current limit over time after the grace period expires using the battery management circuit.

10. The method of claim 8, comprising:
maintaining the merged current limit within one percent of the continuous current limit for a predetermined rest period of time while the present current drawn by the battery is less than or equal to the continuous current limit and the merged current limit.

11. The method of claim 10, comprising:
adjusting the merged current limit toward the peak current limit after the predetermined rest period expires using the battery monitoring circuit.

12. The method of claim 1, wherein the first stage equivalent circuit model includes a second order equivalent circuit model operating in a forward mode accepting the present current draw on the battery as an input, and wherein the internal state of the battery is provided as output and includes an open circuit voltage Voc, an ohmic resistance of the battery R0, a charge transfer resistance R1, a charge transfer capacitance C1, a diffusion resistance R2, a diffusion capacitance C2, a current presently delivered by the battery I, a charge transfer voltage drop VRC1, a diffusion voltage drop VRC2, and a terminal voltage Vt representing a potential difference of the battery.

13. The method of claim 1, wherein the second stage equivalent circuit model includes a second order equivalent circuit model operating in a reverse mode accepting as input a maximum operating voltage of the battery, and the internal state of the battery as inputs, and providing the predicted voltage based current limit as an output.

14. The method of claim 1, wherein the first and second stage circuit models are the same second order equivalent circuit model implemented in the battery management circuit.

15. The method of claim 1, wherein determining a current limit correction factor comprises:
applying a maximum battery voltage and a present terminal voltage of the battery as inputs to a PI or PID controller circuit of the battery management circuit, wherein the PI controller circuit is configured to determine the correction factor.

16. The method of claim 1, comprising:
sending the available power output to a vehicle drive system that includes at least one electric motor arranged and configured to operate as a prime mover for a vehicle, wherein the drive system includes a drive system control circuit configured to except the available power output as input, and wherein the drive system control circuit is operable to reduce power consumed by the electric motor so that power drawn from the battery is less than or equal to the available power output.

17. A method comprising:
determining an internal state of a battery using a battery management circuit configured to determine at least one aspect of the internal state of the battery;
determining a current limit for charge or discharge of a battery according to a second stage equivalent circuit model implemented in the battery management circuit;
comparing the current limit with a measured current using the battery management circuit;
determining a predicted battery voltage based on the current limit and the internal state of the battery according to a third stage equivalent circuit model implemented in the battery management circuit;
determining a correction offset using as inputs the current limit, a present current draw on the battery, and a present power output of the battery using the battery management circuit; and
calculating a power limit by multiplying the battery current limit and the predicted battery voltage using the battery management circuit.

18. The method of claim 17, wherein the internal state of the battery is determined using a present current draw on the battery as input to a first stage equivalent circuit model.

19. The method of claim 17, wherein determining the current limit comprises:
determining a predicted voltage based current limit according to the second stage circuit model accepting as inputs a maximum voltage limit for the battery, and maximum component current limits, wherein the second stage circuit model is a second order equivalent circuit model operating in a reverse mode;
determining a current limit correction factor to be applied to the predicted voltage based current limit using the battery management circuit;
determining a voltage based current limit by combining the predicted voltage based current limit and the correction factor using the battery management circuit; and
determining the current limit using the voltage based current limit, a peak current limit, and a continuous current limit.

20. The method of claim 17, wherein determining a correction offset using the battery management circuit comprises:
receiving the present current draw on the battery;
receiving the present power output of the battery circuit; and
comparing the power limit with a present output power of the battery.

21. The method of claim 20, wherein the battery management circuit includes a PI or PID controller circuit that is configured to accept the present current draw, the present power output, and the power limit as input, and to provide the correction offset as output.

22. The method of claim 17, wherein the second and third stage circuit models are the same second order equivalent circuit model implemented in the battery management circuit.

23. The method of claim 17, comprising:
determining the current limit and the power limit for multiple individual battery cells in a battery array, wherein the battery is one of the multiple individual battery cells in the battery array; and
determining an available power output by adding together the power limit for the multiple individual battery cells in the battery array.

24. The method of claim 17, comprising:
multiplying the power limit by a number of battery cells in a battery array to determine an available power output, wherein the battery is one of the battery cells in the battery array.

25. The method of claim 17, comprising:
sending the power limit to a vehicle drive system that includes at least one electric motor arranged and configured to operate as a prime mover for a vehicle, wherein the drive system includes a drive system control circuit configured to except the power limit as input, and wherein the drive system control circuit is operable to reduce power consumed by the electric motor so that power drawn from the battery is less than or equal to the power limit.
